(19) United States
(12) Patent Application Publication
(10) Pub. No.: US 2025/0022680 A1
(43) Pub. Date: Jan. 16, 2025

(54) 3D VOLUME INSPECTION OF SEMICONDUCTOR WAFERS WITH INCREASED THROUGHPUT AND ACCURACY

(71) Applicant: Carl Zeiss SMT GmbH, Oberkochen (DE)

(72) Inventors: Dmitry Klochkov, Schwaebisch- Gmuend (DE); Johannes Persch, Etgert (DE); Thomas Korb, Schwaebisch- Gmuend (DE); Alex Buxbaum, San Ramon, CA (US); Ramani Pichumani, Palo Alto, CA (US); Eugen Foca, Ellwangen (DE); Jens Timo Neumann, Aalen (DE)

(21) Appl. No.: 18/904,899

(22) Filed: Oct. 2, 2024

Related U.S. Application Data
(63) Continuation of application No. PCT/EP2023/025137, filed on Mar. 28, 2023.
(60) Provisional application No. 63/328,418, filed on Apr. 7, 2022.

(51) Int. Cl. H01J 37/22; G06T 7/00; H01J 37/305

(52) U.S. Cl. CPC H01J 37/222; G06T 7/0004; H01J 37/3056; G06T 2207/10061; H01J 2237/24592; H01J 2237/2803; H01J 2237/2817; H01J 2237/31749

(57) ABSTRACT

A system and a method for volume inspection of semiconductor wafers are configured for milling and fast image acquisition of cross-sections surfaces in an inspection volume. High quality images can be obtained by restriction of the imaging to regions of interest or by averaging over several fast image scans. The method and device can be utilized for quantitative metrology, defect detection, process monitoring, defect review, and inspection of integrated circuits within semiconductor wafers.

### CROSS-REFERENCE TO RELATED APPLICATIONS

The present application is a continuation of, and claims benefit under 35 USC 120 to, international application No. PCT/EP2023/025137, filed Mar. 28, 2023, which claims benefit under 35 USC § 119 (e) of U.S. Provisional Application No. 63/328,418, filed on Apr. 7, 2022. The entire disclosure of each of these applications is incorporated by reference herein.

### FIELD

The present disclosure relates to a three-dimensional circuit pattern inspection method of an inspection volume at an inspection site of a semiconductor wafer. The present disclosure relates to a method, computer program product and a corresponding semiconductor inspection system for determining parameters of 3D objects such as HAR structures in the inspection volume of a semiconductor wafer with increased precision and accuracy. The method employs milling and imaging of a plurality of cross-sections surfaces in an inspection volume and forming a stack of averaged image slices therefrom. Thereby, inspection parameters of 3D objects from the stack of averaged image slices are determined with high accuracy and high robustness. The method, computer program product and device can be used for quantitative metrology, defect detection, process monitoring, defect review, and inspection of integrated circuits within semiconductor wafers.

### BACKGROUND

Semiconductor structures are amongst the finest man-made structures and desirably suffer from very few imperfections only. These rare imperfections are the signatures which defect detection or defect review or quantitative metrology devices are looking for. Fabricated semiconductor structures are based on prior knowledge, for example from design data and fabricated from a limited number of materials and processes. Furthermore, the semiconductor structures are manufactured in a sequence of layers being parallel to the surface of a silicon wafer substrate. For example, in a logic type sample, metal lines are running parallel in metal layers and HAR (high aspect ratio) structures and vias run perpendicular to the metal or alternating conducting/non-conducting layers. The angle between metal lines in different layers is either 0° or 90°. On the other hand, for VNAND type structures it is known that their cross-sections are circular on average and arranged in a regular raster perpendicular to the surface of a silicon wafer. During manufacturing, a huge number of three-dimensional semiconductor structures is generated in a wafer, wherein the fabrication process is typically subject to several influences. Generally, the edge shapes, areas or overlay positions of semiconductor structures may be subject to the property of involved materials, the lithography exposure, or any other involved manufacturing step, such as etching, polishing, deposition, or implantation.

In the fabrication of integrated circuits, the feature size is generally becoming smaller. The current minimum feature size or critical dimension is below 10 nm, for example 7 nm or 5 nm, and approaching below 3 nm in near future. Recently, even minimum feature sizes of 1 nm have been realized. Therefore, measuring edge shapes of patterns, and to determine the dimensions of structures or the line edge roughness with high precision becomes challenging. The measurement resolution of charged particle systems is typically limited by the sampling raster of individual image points or dwell times per pixel on the sample, and the charged particle beam diameter. The sampling raster resolution can be set within the imaging system and can be adapted to the charged particle beam diameter on the sample. The typical raster resolution is 2 nm or below, but the raster resolution limit can be reduced with no physical limitation. The charged particle beam diameter has a limited dimension, which generally depends on the selected type of charged particle, the charged particle beam operation conditions and charged particle lens system utilized. The beam resolution is generally limited by approximately half of the beam diameter. The resolution can be below 3 nm, for example below 2 nm, or even below 1 nm.

With the features sizes of integrated semiconductor circuits becoming smaller, and with the increasing demands on the resolution of charged particle imaging systems, the inspection and 3D analysis of three-dimensional integrated semiconductor structures in wafers becomes more and more challenging. A semiconductor wafer often has a diameter of 300 mm and includes a plurality of several sites, so called dies, each comprising at least one integrated circuit pattern such as for example for a memory chip or for a processor chip. Semiconductor wafers typically run through about 1000 process steps, and within the semiconductor wafer, about 100 and more parallel layers are often formed, comprising the transistor layers, the layers of the middle of the line, and the interconnect layers and, in memory devices, a plurality of 3D arrays of memory cells.

A common way to generate 3D tomographic data from semiconductor samples on nm scale is the so-called slice and image approach performed for example by a dual beam device. A slice and image approach is described in WO 2020/244795 A1. According to the method of the WO 2020/244795A1, a 3D volume inspection is obtained at an inspection sample extracted from a semiconductor wafer. This method involves destroying the sample to obtain an inspection sample. This has been addressed by utilizing the slice and image method under a slanted angle into the surface of a semiconductor wafer, as described in WO 2021/180600 A1. According to this method, at least a first inspection site is determined, and 3D volume image of an inspection volume is obtained by slicing and imaging a plurality of cross-section surfaces of the inspection volume. In a first example for a precise measurement, a large number N of cross-section surfaces of the inspection volume is generated, with the number N exceeding 100 or even more averaged image slices. For example, in a volume with a lateral dimension of 5 μm and a slicing distance of 5 nm, 1000 slices are milled and imaged. For the alignment and registration of the cross-section averaged image slices, a plurality of different methods has been proposed. For example, reference marks or so-called fiducials can be employed, or a feature-based alignment can be employed. However, according to recent demands and in many application examples, these methods turned out to involve further improvements of the alignment and registration of the plurality of cross-section images slices.

According to several inspection tasks, a full 3D volume image with high accuracy and high throughput is desired. In an example, the task of the inspection is to determine a set of specific parameters of semiconductor objects such as high aspect ratio (HAR)—structures inside the inspection volume with high precision. For a fast image acquisition with fast scan times, the signal to noise ratio (SNR) is typically very low. Known approaches utilize for example long dwell times, increasing the dwell time per pixel. In other examples, a single image acquisition may be replaced by a fast scanning and addition of several images to obtain a similar SNR of a single scan with long dwell times. These methods can come with several downsides. First, the image acquisition for high SNR can be very time consuming, slowing down the volume image acquisition to only few inspections sites per hour. Second, accumulated charging with primary charged particles and thus large currents of primary charged particles can lead to high charging effects in a wafer sample, which can deteriorate the image generation. Third, during the long times for image acquisition, the inspection system may show significant drift. The drift is of increasing importance with the increased demands on resolution, which is currently below 5 nm. Near future demands for resolution will be below 3 nm, below 2 nm or even less. Therefore, already drifts or vibrations in the order of few nm during image acquisition of the stack of 2D averaged image slices causes unacceptable shearing.

In addition, in some applications, the methods described in WO 2021/180600 A1 do not provide sufficient information for the determination of a set of parameters of complex semiconductor structures.

### SUMMARY

The disclosure seeks to provide improved slice- and image-methods.

The disclosure seeks to provide a wafer inspection method for the inspection of three-dimensional semiconductor structures in inspection volumes with higher accuracy, more information and higher speed.

The disclosure can provide an improvement to the slice- and image-method to generate a 3D volume image of an inspection volume of a wafer sample.

The investigation of a semiconductor object can include the reconstruction of a 3D shape of a semiconductor object of interest from a 3D volume image, formed by a stack of 2D averaged image slices. The stack of 2D averaged image slices is obtained by imaging of a series of cross section surfaces with a charged particle beam imaging device, for example a SEM (scanning electron microscope) or a HIM (Helium ion microscope), and by repeated milling of cross-section surfaces in an inspection volume of a wafer sample with a FIB. A typical stack of 2D averaged image slices of a 3D volume image can contain between a few hundred averaged image slices up to more than 1000 averaged image slices.

In an example, the axis of the charged particle beam imaging device is arranged perpendicular to a surface of a wafer sample and the 2D averaged image slices contain cross-sections of the semiconductor objects of interest, e.g., memory (VNAND) structures such as High-Aspect-Ratio (HAR) channels. In an example, the wafer sample is given by a complete wafer and the cross-section surfaces are milled by a FIB arranged under a slanted angle to the wafer surface.

According to a first embodiment of the disclosure, a method of image formation of a stack of M averaged image slices with increased throughput and accuracy is provided. The method of image formation of a stack of M averaged image slices according to the first embodiment utilizes an acquisition of a large number of N cross section images by fast milling and fast image scanning of a plurality of cross section surfaces through an inspection volume. According to the first embodiment, the lengthy process of acquiring high quality images for a plurality of cross section surfaces is no longer required. Instead, a stack of M high quality images slices is determined according to a moving mean value of the first plurality of N cross section images. According to the first embodiment, less image scanning time is used for the acquisition of each cross-section image and a large number of cross-section images is generated, each having a higher noise level.

In an example, the number M is less than the number N of cross section images, with M<=N multiplied by a factor A; with the factor A>=3, for example A=5, A=7 or A=20 or more. The number N of cross section images is typically between a number Q of the plurality of cross section surfaces and two times the number of cross section surfaces, with 2×Q=>N=>Q. The method of image acquisition of a stack of M averaged image slices according to the first embodiment relies on the typical property of semiconductor objects of interest, for example HAR channels, which are expected to change in a predetermined direction only slightly. By computing a moving mean value or average in a predetermined direction over many cross-section images, noise is effectively reduced and a time for image acquisition can be reduced. Furthermore, the milling time for the generation of cross section surfaces is more effectively used by generation of even more and denser cross sections with smaller distance between the cross sections.

Between each subset of the cross-section images of cross section surfaces at small milling distance, changes of the semiconductor object of interest are typically limited. Therefore, an alignment and compensation of lateral drifts can be a computationally simple operation, either by best determining best matching conditions or by determining the contrast or edge slope in each averaged image slice. By acquisition of a large number N of cross-section images of different cross-section surfaces formed in the inspection volume, a drift of a stage or a charged particle beam column can be determined from the cross-section images and effectively removed for the determination of the moving mean value. In an example, a plurality of cross-section surfaces is milled by a FIB through an inspection volume with a small z-distance of for example 2 nm, 3 nm or 5 nm. Each cross-section surfaces is imaged at least once by a fast scanning operation with the charged particle beam imaging device and for each cross-section surface, at least one cross-section image is obtained. After or during the image acquisition, a moving mean value over a subset of cross-section images is determined. During the determination of the mean value, an image contrast is evaluated for example by computing gradients in the moving mean value images; if an overall low gradient or low contrast is detected in a specific direction, the determination of the mean value is optimized by including lateral shifts to the cross-section images. Thereby, the effect of a drift in that specific direction is reduced. During an optimization of the drift compensation, the maximum expected drift may be limited to reduce computational time and increase robustness of the method. A drift can be determined as an absolute drift of each cross-section image relative to a reference, or as a relative drift to for example a previous cross-section image. Different registration or alignment methods may be employed to enhance the speed and performance of the drift compensation. In certain instances, manual verification of a drift compensation is possible and wrong image shifts can be discarded.

In an example, the texture filling in the cross-section surfaces can change. For example, a semiconductor structure can comprise several different stacks or decks of semiconductor features, which are stacked on top of each other. Cross-section images can thus comprise image segments of different decks. For example, by milling under slanted angle, a cross-section surface through a first VNAND deck and at least a second VNAND deck. The position of the transition zones between two decks gradually varies over the cross-section images. Subsequent cross-sectional images share image segments or regions from the same deck with the same texture (e.g., regions showing channel cross sections of the upper VNAND deck) but have also regions of different texture (e.g., the deck transition). In such cases the registration to determine the lateral shifts should be restricted to regions showing the same texture so that the moving averaging is not compromised.

In an example, the formation of the M averaged image slices is achieved by a one-dimensional (1D) numerical convolution from the large number N of cross section images with a convolution kernel. In an example, the large number N of cross-section images form a 3D data set with transversal coordinates x and y of each image, and the different z-coordinates are corresponding to the predetermined direction. The moving mean value or average is described by a convolution with a 1D convolution kernel over the z-coordinate of the 3D data set. The convolution kernel can be a function over a predetermined number of cross section images, for example a moving rect-function or a moving gaussian kernel in z-direction. Other convolution kernels for computing different weighted moving averages point wise median filters are possible as well. Other examples of convolution kernels are corresponding to filters for finding a minimum of a norm or matching function according to a given noise model. The width of the convolution kernel can be predetermined or can be adaptive in accordance with a local noise level or a desired SNR of the resulting M averaged image slices. In other examples, machine learning based algorithms may be applied the optimally perform the computation of the moving averaging values.

According to the first embodiment, less image scanning time is used for the acquisition of each cross-section image and many cross-section images are generated. For each new image scan, any milling artefact of a previous cross section image is removed, and defects or artefacts of the milling operation may change from cross section surface to cross section surface. According to the first embodiment of the disclosure, at least some of these milling artefacts are averaged out with the formation of the moving average. The depth of field of a charged particle beam imaging system is quite low and a perfect focus is hard to achieve. By averaging over a plurality of cross section images, focusing defects of individual cross-section images are averaged and averaged image slices of higher definition are generated.

According to the first embodiment of the disclosure, many cross-section images are obtained with reduced scanning times, and therefore increased noise level. The stack of M averaged image slices is formed by averaging. Thereby, the increased noise level of the quickly acquired cross section images is reduced and averaged image slices with increased SNR are formed.

During the determination of a moving average, global drifts can be detected and compensated, while individual deviations of the trajectories of for example HAR channels can still be detected. Further alignment and registration of the cross-section images at fiducials or image features present in the semiconductor is possible as well.

The image acquisition can either be performed by interchanging image scanning and milling operation or by interlaced imaging and milling. The computation of the averaged image slices can be performed during the image acquisition according to the slice and image method, and thereby the memory demand for storing the plurality of N cross section images is reduced.

The method according to the first embodiment can further be applied to generate training data for an inspection method using machine learning. Annotation can be transferred from averaged image slices of low noise level to the set of cross-section images used for the averaging, each with large noise level and acquired by fast image scanning. According to a second embodiment of the disclosure, the method of image formation of a stack of M averaged image slices with increased throughput and accuracy is provided, and an accuracy of the image formation is even further improved. According to the second embodiment, image acquisition and milling operation are interlaced and performed at the same time, and the image acquisition of N cross-section images and the milling of N cross section surfaces are performed at the same time. In an example, the milling by a FIB is performed by the FIB beam arranged in a direction in the Y-Z-plane, with a milling angle GF to the y-axis. The FIB is scanned along a first direction (the x-direction), perpendicular to the FIB beam. At the same time, an image acquisition with an imaging charged particle beam is performed by fast scanning the imaging charged particle beam across the cross-section surface in x-direction and stepping in y direction.

Thereby, the large number N of cross-section images is obtained, wherein each cross-section image of each interlaced milling- and imaging operation comprises a first area according to a cross-section surface before the actual milling operation and a second area according to a cross-section surface after the actual milling operation. Each cross-section image therefore comprises image areas of different z-positions in the stack of cross section images. The large number N of cross-section images form again a 3D data set with transversal coordinates x and y of each image, and the different z-coordinates corresponding to the two areas within each cross-section images. Thereby, an impact of a drift between different cross section images can even further be reduced. The method according to the second embodiment can be combined with a method according to the first embodiment, and a stack of M averaged image slices can be formed by determining a moving mean value or average as described in the first embodiment.

According to an example, it is possible to selectively add further cross-section images by for example a repeated image scan. For example, a first set of cross-section images can be obtained parallel to a milling operation as described in the second example, and a second set of cross-section images can be obtained between two subsequent milling operations.

The throughput of the method for inspection of a 3D semiconductor object of interest in an inspection volume of a wafer sample can further be improved by limiting the performance of the time-consuming image scanning operation to selected regions of interest.

According to a third embodiment of the disclosure, a method of image formation of a stack of M averaged image slices is further improved and the throughput of the image formation is even further increased. According to the third embodiment, the time for obtaining each cross-section image is reduced by limiting the image scan to at least one region of interest (ROI).

A full-scale 3D volume data generation using the slice-and-imaging method provides the most complete information about an inspection volume in a wafer sample. However, a slice-and-imaging approach generates inconveniently large data volumes. On the other hand, a fully reconstructed inspection volume often contains a lot of redundant information which is not contributing to a particular semiconductor object of interest and not required for a measurement or a set of measurements. At the same time, the image quality, resolution, and pixel size in the vicinity of the features of interest is often compromised to reduce the acquisition/processing time as well as the data volume. It is therefore desirable to have a possibility to adjust the imaging and milling parameters such an image scanning is limited to cross sections intersecting with regions of a volume of interest inside the inspection volume. With the method according to the third embodiment, the total acquisition time of a relevant 3D volume data of a semiconductor object of interest is even further reduced.

A method of inspection of a 3D semiconductor object of interest in an inspection volume of a wafer sample according to the third embodiment comprises the step of defining at least a first volume of interest in an inspection volume of a semiconductor wafer, the first volume of interest being withing the inspection volume. In an example, the region of interest (ROIs) is formed by at least one volume of interest inside the inspection volume and the ROI of subsequent cross section images is determined according to the overlap with the at least one volume of interest. In an example, the volume of interest is buried deep in the inspection volume below the surface of a wafer.

The method further comprises the steps of milling a plurality of cross section surfaces through the inspection volume and acquiring a number of cross section image segments by performing image scanning operations of cross-section surface segments withing the at least first volume of interest. In an example, the milling is performed at a slanted angle to a wafer surface and at least first volume of interest is oriented perpendicular to the wafer surface.

In an example, the at least first volume of interest is defined according to CAD data. The method can further comprise the step of aligning the at least first volume of interest within the inspection volume according to at least a first image scan of a first cross-section surface within the inspection volume. From the first image scan, a precise position of the inspection volume within the wafer is obtained and registered, and the position of the volume of interest can be precisely determined. In an example, the step of aligning comprises further re-alignment of the at least first volume of interest at second or further image scans of at least a second and further cross-section surfaces within the inspection volume. Thereby, the position of the volume of interest can be precisely maintained even in presence of for example milling deviations.

For example, in a regular arrangement of HAR channels, a region of interest can comprise only one column or one row of HAR channels. First, the regions of interest are made accessible for imaging by performing a milling operation with the FIB beam. Thereby, cross section surfaces are formed which cover the at least one ROI. After detection of a region of interest, the image acquisition by the imaging charged particle beam is reduced to the at least on ROI. Thereby, a time for image acquisition is reduced. The at least on ROI can have a complex shape, for example a cross or T-shape formed by a column and a row of HAR channels. The at least on ROI can also be formed by several disjunct ROIs, which are distributed over each cross-section surface. An ROI can also be a function of the z-coordinate or depth of the cross-section surfaces formed in the inspection volume of a wafer and can follow a 3D shape of a semiconductor object of interest. The z-dependency of a size, shape and a position of a ROI can be predetermined according to prior information of the semiconductor object of interest. A tracking of an unknown semiconductor object of interest can be guided by model-based assumptions, or by using machine learning-based techniques to track the trajectories of structures in the inspection volume.

In an example, changes of a semiconductor of interest are expected to be limited to certain regions within an inspection volume. The expectation can be triggered by a priori information, comprising CAD information or information obtained from other inspection volumes. According to an example of the method according to the third embodiment, a throughput is even further increased by an adaptive change of the distance between two adjacent cross-section surfaces. The method thus comprises a step of adjusting a distance between two adjacent cross-section surfaces based on prior information of the semiconductor object of interest within the at least first volume of interest. In an example, two adjacent volumes of interests are defined, and an alignment of different layer stacks of a semiconductor sample can be determined.

In an example, the at least first volume of interest is determined during the milling of the plurality of cross section surfaces into the inspection volume. According to the method, the step of defining the at least first volume of interest comprises the steps of:
a) acquiring a first image scan of a first cross-section surface,
b) selecting a first cross-section image segment in the first image scan, the first cross-section image segment is including a cross section of a semiconductor object of interest,
c) milling of a second cross-section surface into the inspection volume of the wafer sample,
d) selecting a second cross-section image segment by projecting the first cross-section image segment onto the second cross-section surface,
e) acquiring a second cross-section image segment of the second cross-section surface segment.
f) repeating steps c) to e) by milling further cross-section surfaces, selecting and acquiring further cross-section image segments until a predefined interruption criterion is met.

The first cross-section image segment is corresponding to the cross section through the volume of interest within the first image scan. In the first image scan, the cross section through the volume of interest is determined by the cross section of the semiconductor object of interest, with a boundary area in the circumference of the cross section of the semiconductor object of interest. The cross section of the semiconductor object of interest can be determined by image processing, pattern recognition, template matching or machine learning operations, or a combination of these method, and by using CAD information.

In an example, the center of gravity of cross section of the semiconductor object of interest is corresponding to the center of gravity of the first cross-section image segment. After milling a second or further cross-section surface, the first cross-section image segment is projected onto the second of further cross-section surface, and an image of the second of further cross-section surface with the first cross-section image segment is obtained. The cross section of the semiconductor object of interest is again determined by image processing, pattern recognition, template matching or machine learning operations, or a combination of these method, and a center of gravity of the semiconductor object of interest is determined. If the center of gravity of the semiconductor object of interest deviates from the center of the first, projected cross-section image segment, the first cross section image segment is adjusted to form a second or adjusted cross section image segment with the center of gravity of the semiconductor object of interest coinciding with the center of the second, adjusted projected cross-section image segment. This method of adjustment is applied from cross section surface to cross section surface and the volume of interest is continuously adjusted through the milling operations and image acquisition throughout the inspection volume.

In an example, the method further comprises the step of adjusting of a position or of a size of the first cross-section image segment according to the second cross-section image segment, wherein the position and size of the cross section of semiconductor object of interest within the second cross-section image segment is analyzed by image processing. In an example of step e), the projecting the first cross-section image segment onto the second cross-section surface is performed in a predetermined direction, for example in a direction parallel to a HAR channel. In such an example, the predetermined direction is oriented perpendicular to a wafer surface.

In an example of a method according the third embodiment, a fast cross section image scan of a cross section surface is obtained by fast image scanning, and a cross section image with reduced SNR is generated. In the cross-section image with low SNR, a region of interest of a volume of interest is determined and an image acquisition with increased dwell time and increased SNR is generated only for the region of interest. The step of fast image acquisition and determination of region of interest in a fast acquire cross-section image with low SNR can be repeated.

In an example, the method of the third embodiment comprises the step of generating a 3D volume image of the 3D semiconductor object of interest. The 3D volume image desirably is not limited to the volume of interest, comprising the 3D semiconductor object of interest, but can be formed for the entire inspection volume. In an example, the 3D volume image of the inspection volume comprises the 3D volume image of the at least first volume of interest and augmented 3D image data from prior information outside the at least first volume of interest. The augmented 3D image data can be obtained from CAD data or from a previously acquired 3D volume image of a reference volume

The method according to the third embodiment can be combined with the methods according to the first or second embodiment described above. Thereby, the formation of the M averaged image slices from N cross section images is reduced to the determination of a moving mean value withing the at least one volume of interest. Furthermore, in an interlaced operation, a first volume of interest can be in an area of a first z-position before an actual milling operation, and a second volume of interest can be in an area of a second z-position after an actual milling operation.

According to a fourth embodiment of the disclosure, a method of image formation of a stack of M averaged image slices is further improved and the throughput of the image acquisition is even more increased. According to the fourth embodiment, a method of sparse imaging is applied. The effect of sparse imaging is similar to the method according to the third embodiment, but with a plurality of small ROIs. For example, in a plurality of HAR channels, it is often possible to reduce the image acquisition to few HAR channels or even to details of HAR channels. The method according to the fourth embodiment relies on prior knowledge about the semiconductor objects of interest in the inspection volume. During the sparse image acquisition, the image acquisition is reduced to sparse image sampling positions, and each averaged image slice is filled with augmented information according to prior knowledge. The augmented information can for example be derived according to a CAD model of the semiconductor objects of interest, which is modified to best match with the image data of the sparse image sampling positions. The sparse image sampling positions can be predetermined according to prior information, for example from CAD data of the semiconductor objects of interest. The method according to the fourth embodiment can be combined with any of the methods according to the first to third embodiments described above, and a throughput of a wafer inspection task can be improved.

With the fast image acquisition methods of the first embodiment of the disclosure, the imaging parameters of the charged particle imaging system can be optimized for the detection of a specific semiconductor object of interest. The optimization can for example include the selection of the detection method for the detection of interaction products generated at each cross-section surface. In some examples there can arise the drawback that an enhancement of the detection of specific semiconductor features is achieved at the expense of other semiconductor features. For example, when imaging semiconductor memory wafers, the detection of HAR channel boundaries may conflict with the parameters used to accurately detect word line layers. Alternatively, detecting accurate HAR channel boundaries may conflict with the ability to detect recess etch boundaries. This problem becomes more acute when performing destructive milling according to the slice- and image approach, where images cannot be reacquired for cross-section surface layers that have already been removed.

According to a fifth embodiment of the disclosure, a method of fast image formation of a stack of M averaged image slices is further improved and the accuracy of the image acquisition is even more increased. The method of the fifth embodiment employs a multi-modal image acquisition, comprising at least a first and a second imaging mode of operation of the charged particle beam imaging system for an improved accuracy of the image formation of the stack of M averaged image slices. In an example, variations of the imaging settings or imaging modes can be used to differentiate imaged structures by elemental composition while being less sensitive to topography contrast or surface effects. The imaging modes can be modified and combined and information in a fast acquired image scan is enhanced by information from different imaging modes.

According to a first example, during at least an imaging mode of operation, a detector property is adjusted. For example, a detector gain is adjusted to a low signal level, and during a second imaging mode of operation, a detector gain is adjusted to a high signal level. Thereby, the signals obtained by a detector are adjusted to for example different ROIs within an inspection task. According to a further example, a cut-off energy of secondary or backscattered electrons is adjusted. Thereby, for example an imaging can be reduced to certain depths within a sample below a cross section surface or certain materials.

According to a second example, the different imaging modes are achieved by utilizing separate or different detectors. For example, a first detector and a second detector can be arranged in different angular segments and be configured to determine a topography contrast. For example, a first detector can be configured to collect large angle scattered electrons, and a second, in-lens-detector can be configured to collect small angle backscattered electrons. For example, a first detector can be an electron detector and a second detector can be an X-ray detector. With the multi-modal image acquisition, the image formation of a stack of M averaged image slices is further improved by obtaining additional information.

In an example, the method comprises a step of changing a detection mode between to subsequent image scanning operations, wherein a change of a detection mode comprises at least one of a change of a dynamic range, a change of an energy range of interaction products, or a change of a type of interaction products.

The method according to the fifth embodiment can be combined with the methods according to any of the first to fourth embodiments for each imaging mode of the multi-modal imaging. For example, different convolution kernels can be applied for each of the z-stack of cross-section images of each imaging mode. Thereby, high SNR can be achieved in all imaging modes in parallel. Different multi-modal imaging modes can also be applied to selected ROIs or to sparse imaging positions. With the additional information of the multi-modal imaging, the desired information about the semiconductor object of interest and the accuracy of the image formation is further improved at no reduction of the throughput improvements according to the first to fourth embodiments.

According to a sixth embodiment, an inspection system for 3D inspection of a semiconductor object of interest in an inspection volume of a wafer is provided. The inspection system configured for performing the methods according to any of the first to fifth embodiment comprises a wafer sample holder and stage for holding and positioning the wafer sample. The inspection system comprises a dual beam device comprising a FIB column and a charged particle beam imaging system, for example a scanning electron microscope (SEM) or a Helium ion microscope (HIM). In another example, a corrected electron microscope with a plurality of detectors for angular resolved imaging of interaction products is applied. Such a corrected electron microscope is described in German patent application 102021212203.5, filed on Oct. 28, 2021, which is incorporated herein by reference. Both columns of the dual beam device are arranged at an angle and forming an intersection point of the optical axes of the columns. The stage is configured for positioning and holding a sample comprising an inspection volume in proximity to the intersection point. The dual beam device further comprises at least one detector for secondary or backscattered charged particles. In an example, the dual beam device further comprises at least a second detector for acquiring a second signal according to a multi-modal imaging operation. The inspection system further comprises a control unit to control the operation of the dual beam device. The inspection system further comprises a memory for storing software program code, operations instruction program code and a memory for storing the acquired digital image data. The inspection system further comprises a processor configured for performing the processing instructions for the determination of moving averages. The inspection system is further configured to receive prior information, for example CAD information.

According to an example, the charged particle imaging system of the dual beam device is configured for performing different imaging modes. Different imaging modes can comprise different detectors or detectors configured for different detector settings. A detector can comprise a grid with a variable grid voltage. Thereby, a detector setting can be changed by selection of a repelling field to cut off charged interaction products of low energy. A detector can comprise a variable analogue gain factor, configured for the adjustment of an analogue signal before conversion into a digital signal. Thereby, weak signals can be obtained with higher accuracy and detail.

An example of a charged particle imaging system comprises a scanning deflector and a scan controller, configured for performing different image scanning operations, for example including the performance of a line averaging, a variation of a dwell time, a variation of a scan path, for example a zig-zag scan strategy, or a meander scan strategy.

An example of a charged particle imaging system configured for performing different imaging modes according to the fifth embodiment comprise a source of charged particle and particle optical elements, configured for a variation of an acceleration voltage, a beam current, a charged particle beam angle, a numerical aperture of the charged particle beam, or a cross sectional shape of the charged particle beam.

An example of a charged particle imaging system comprises correction means for chromatic and spherical aberration, allowing for an inspection with higher resolution at lower electron voltages of below 1 keV, for example below 500 eV.

According to the embodiments of the disclosure, the acquisition time of a 3D volume image of a semiconductor object of interest by the slice- and image-method is reduced, and an image accuracy is increased. Thereby, the throughput of an inspection task is increased and an inspection system for 3D inspection of a semiconductor object of interest is provided with increased throughput and increased accuracy. An inspection system for volume inspection of semiconductor wafers with increased accuracy and throughput is provided. The inspection system is configured for a milling and imaging of a plurality of cross-sections surfaces in an inspection volume and determining inspection parameters of the 3D objects from the plurality of cross-section surface images. The disclosure provides a device and a method for 3D inspection of an inspection volume in a wafer and for the determination of a set of parameters of semiconductor features inside of the inspection volume with high accuracy and higher throughput. The methods and system configured for performing a method can be utilized for quantitative metrology, defect detection, process monitoring, defect review, and inspection of integrated circuits within semiconductor wafers.

The disclosure described by examples and embodiments is not limited to the embodiments and examples but can be implemented by those skilled in the art by various combinations or modifications.

### BRIEF DESCRIPTION OF THE DRAWINGS

The present disclosure will be even more fully understood with reference to the following drawings:

FIG. 1 shows an illustration of an inspection system for 3D volume inspection with a dual beam device.

FIG. 2 is an illustration of a method of volume inspection in a wafer with a slanted cross-section milling and imaging by the dual beam device.

FIG. 3 illustrates an example of an averaged image slice

FIG. 4 shows an illustration of a method according to the first embodiment

FIGS. 5A-5B show an illustration of the number of cross section surfaces and the data stack of cross section images

FIG. 6 shows a first example of the computation of averaged image slices

FIG. 7 shows a second example of the computation of averaged image slices

FIG. 8 shows a third example of the computation of averaged image slices

FIG. 9 shows an example of a scanning acquisition of a cross section image parallel to a milling operation according to the second embodiment

FIG. 10 shows a further example of the computation of averaged image slices

FIG. 11 shows a method according the third embodiment with a limited volume of interest

FIG. 12 illustrates a first example of the third embodiment

FIGS. 13A-13B illustrate a second example of the third embodiment

FIG. 14 illustrates a further example of the third embodiment with a dynamic adjustment of regions of interest

FIG. 15 illustrates a further example of the third embodiment with the determination of an overlay or alignment error

FIG. 16 shows a method according to the fourth embodiment

FIGS. 17A-17B illustrate an example of the fourth embodiment of sparse image acquisition

FIG. 18 shows an illustration of an inspection system for 3D volume inspection with a dual beam device with a corrected electron microscope.

### DETAILED DESCRIPTION

Throughout the figures and the description, same reference numbers are used to describe same or similar features or components. The coordinate system is selected that the wafer surface 55 coincides with the XY-plane.

Recently, for the investigation of 3D inspection volumes in semiconductor wafers, a slice and imaging method has been proposed, which is applicable to inspection volumes inside a wafer. Thereby, a 3D volume image is generated at an inspection volume inside a wafer in the so called “wedge-cut” approach or wedge-cut geometry, without the need of a removal of a sample from the wafer. The slice- and image method is applied to an inspection volume with dimensions of few μm, for example with a lateral extension of 5 μm to 10 μm or up to 50 μm in wafers with diameters of 200 mm or 300 mm. A V-shaped groove or wedge is milled in the top surface of an integrated semiconductor wafer to make accessible a cross-section surface at a slanted angle to the top surface. 3D volume images of inspection volumes are acquired at a limited number of measurement sites, for example representative sites of dies, for example at process control monitors (PCM), or at sites identified by other inspection tools. The slice and image method will destroy the wafer only locally, and other dies may still be used, or the wafer may still be used for further processing. The methods and inspection systems according to the 3D Volume image generation are described in WO 2021/180600 A1, which is fully incorporated herein by reference. The current disclosure is an improvement and extension to the methods and inspection systems according to the 3D Volume image generation, where a higher throughput is involved. One of the achievements of the disclosure of the slice-and-imaging approach for the inspection of semiconductor devices is the reduction of the imaging time for the acquisition of a plurality of averaged image slices.

The disclosure is applicable for semiconductor devices that include semiconductor-elements with high aspect ratio and/or located in multiple layers inside the device. Manufacturing of such devices strongly relies on the ability to characterize the semiconductor-elements in 3D. The full-scale 3D tomography according to the improved method and apparatus of the disclosure are using an improved slice-and-imaging technique with increased throughput.

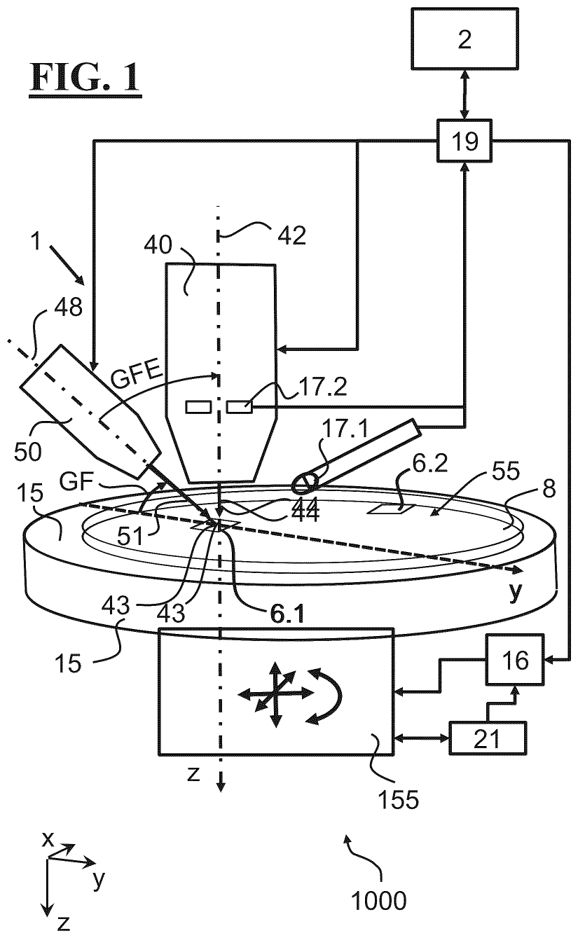

An inspection system of the disclosure is illustrated in FIG. 1. According to the first embodiment, an improved wafer inspection system 1000 for 3D volume inspection is given. The improved wafer inspection system 1000 for high-throughput 3D volume inspection is configured for a slice- and imaging method under wedge cut geometry with a dual beam device 1. For a wafer 8, several measurement sites, comprising measurement sites 6.1 and 6.2, are defined in a location map or inspection list generated from an inspection tool or from design information. The wafer 8 is placed on a wafer support table 15. The wafer support table 15 is mounted on a stage 155 with actuators and position control 21. Actuators and means for precision control 21 for a wafer stage 155 such as Laser interferometers are known in the art. A control unit 16 receives information about the actual position of the wafer stage 155 and is configured to control the wafer stage 155 and to adjust a measurement site 6.1 of the wafer 8 at the intersection point 43 of the dual-beam device 1. The dual beam device 1 comprises a FIB column 50 with a FIB optical axis 48 and a charged particle beam (CPB) imaging system 40 with optical axis 42. At the intersection point 43 of both optical axes of FIB and CPB imaging system, the wafer surface 55 is arranged at a slant angle GF to the FIB axis 48. FIB axis 48 and CPB imaging system axis 42 include an angle GFE. In the coordinate system of FIG. 1, the normal to the wafer surface 55 is given by the z-axis. The focused ion beam (FIB) 51 is generated by the FIB-column 50 and is impinging under angle GF on the surface 55 of the wafer 8. Slanted cross-section surfaces are milled into the wafer by ion beam milling at the inspection site 6.1 under approximately the slant angle GF at a predetermined y-position, which is controlled by the stage 155 and position control 21. In the example of FIG. 1, the slant angle GF is approximately 30°. The actual slant angle of the slanted cross-section surface can deviate from the slant angle GF by up to 1° to 4° due to the beam divergency of the focused ion beam, for example a Gallium-Ion beam, or due to variable material properties with respect to milling along the cross-section surface. With the charged particle beam imaging system 40, images of the milled surfaces are acquired. In the example of FIG. 1, the charged particle beam imaging system 40 is arranged with its charged particle beam 44 perpendicular to the wafer surface 55 and parallel to the z-axis. In other configurations, the optical axis 42 of the charged particle beam imaging system 40 is arranged at an angle to the z-axis.

During imaging, a beam of charged particles 44 is scanned by a scanning unit of the charged particle beam imaging system 40 along a scan path over a cross-section surface of the wafer at measurement site 6.1, and secondary particles as well as backscattered particles are generated. Particle detector 17.1 and optional internal particle detector 17.2 collect at least some of the secondary particles and/or backscattered particles and communicate the particle count with a control unit 19. Other detectors for other kinds of interaction products such as x-rays or photons may be present as well. Control unit 19 is in control of the charged particle beam imaging column 40 and of the FIB column 50 and connected to a control unit 16 to control the position of the wafer mounted on the wafer support table 15 via the wafer stage 155. Operation control unit 2 communicates with control unit 19, which triggers placement and alignment for example of measurement site 6.1 of the wafer 8 at the intersection point 43 via wafer stage movement and triggers repeatedly operations of FIB milling, image acquisition and stage movements. Control unit 19 and Operation control unit 2 comprises a memory for storing instructions in form of software code and at least one processer to execute during operation the instructions, for example to execute the methods described in the first to fourth embodiments. A memory is further provided to store digital image data. Operation control unit 2 may further comprise a user interface or an interface to other communication interfaces to receive instructions, prior information and to transfer inspection results.

Each new cross-section surface is milled by the FIB beam 51, and imaged by the charged particle imaging beam 44, which is for example scanning electron beam of a SEM or a Helium-Ion-beam of a Helium ion microscope (HIM).

The operation control unit 2 is configured to perform a 3D inspection inside an inspection volume 160 in a wafer 8. The operation control unit 2 is further configured to reconstruct the properties of semiconductor structures of interest from the 3D volume image. In an example, features and 3D positions of the semiconductor structures of interest, for example the positions of the HAR structures, are detected by the image processing methods, for example from HAR centroids. A 3D volume image generation including image processing methods and feature based alignment is further described in WO 2020/244795 A1, which is hereby incorporated by reference.

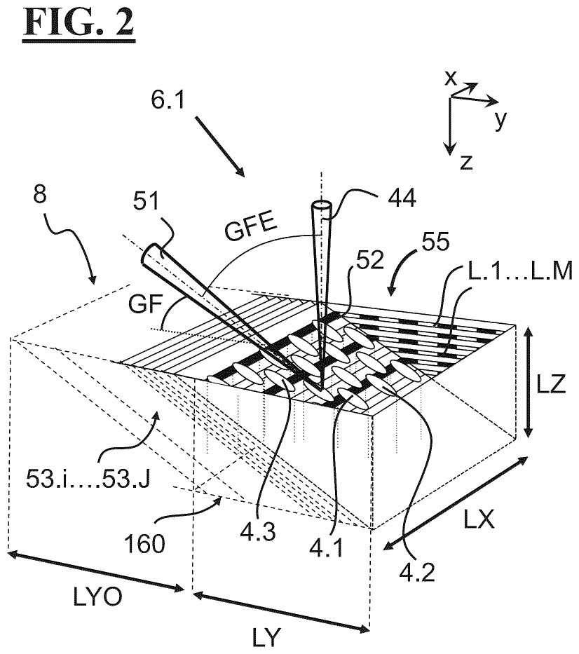

FIG. 2 illustrates further details of the slice and imaging method in the wedge cut geometry. By repetition of the slicing and imaging method in wedge-cut geometry, a plurality of J cross-section averaged image slices comprising averaged image slices of cross-section surfaces 52, 53.i . . . 53.J is generated and a 3D volume image of an inspection volume 160 at an inspection site 6.1 of the wafer 8 is generated. FIG. 2 illustrates the wedge cut geometry at the example of a 3D-memory stack. The cross-section surfaces 53.1 . . . 53.J are milled with a FIB beam 51 at an angle GF of approximately 30° to the wafer surface 55, but other angles GF, for example between GF=20° and GF=60° are possible as well. FIG. 2 illustrates the situation, when the surface 52 is the new cross-section surface which was milled last by FIB 51. The cross-section surface 52 is scanned for example by SEM beam 44, and a high-resolution cross-section averaged image slice is generated. The cross-section averaged image slice comprises first cross-section image features, formed by intersections with high aspect ratio (HAR) structures or vias (for example first cross-section image features of HAR-structures 4.1, 4.2, and 4.3) and second cross-section image features formed by intersections with layers L.1 . . . . L.M, which comprise for example SiO2, SiN- or Tungsten lines. Some of the lines are also called “word-lines”. The maximum number M of layers is typically more than 50, for example more than 100 or even more than 200.

The HAR-structures and layers extend throughout most of the inspection volume in the wafer but may comprise gaps. The HAR structures typically have diameters about or below 100 nm, for example about 80 nm, or for example 40 nm. The HAR structures are arranged in a regular, for example hexagonal raster with a pitch of about below 300 nm, for example even below 200 nm. The cross-section averaged image slices contain therefore first cross-section image features as intersections or cross-sections of the HAR structures at different depth (Z) at the respective XY-location. In case of vertical memory HAR structures of a cylindrical shape, the obtained first cross-sections image features are circular or elliptical structures at various depths determined by the locations of the structures on the sloped cross-section surface 52. The memory stack extends in the Z-direction perpendicular to the wafer surface 55. The thickness d or minimum distances d between two adjacent cross-section averaged image slices is adjusted to values typically in the order of few nm, for example 30 nm, 20 nm, 10 nm, 5 nm, 4 nm or even less. Once a layer of material of predetermined thickness d is removed with FIB, a next cross-section surface 53.i . . . 53.J is exposed and accessible for imaging with the charged particle imaging beam 44.

A plurality of J cross-section averaged image slices acquired in this manner covers an inspection volume of the wafer 8 at measurement site 6.1 and is used for forming of a 3D volume image of high 3D resolution below for example 10 nm, such as below 5 nm. The inspection volume 160 (see FIG. 2) typically has a lateral extension of LX=LY=5 μm to 15 μm in x-y plane, and a depth LZ of 2 μm to 15 μm below the wafer surface 55. However, the extensions can also be larger and reach for example 50 μm.

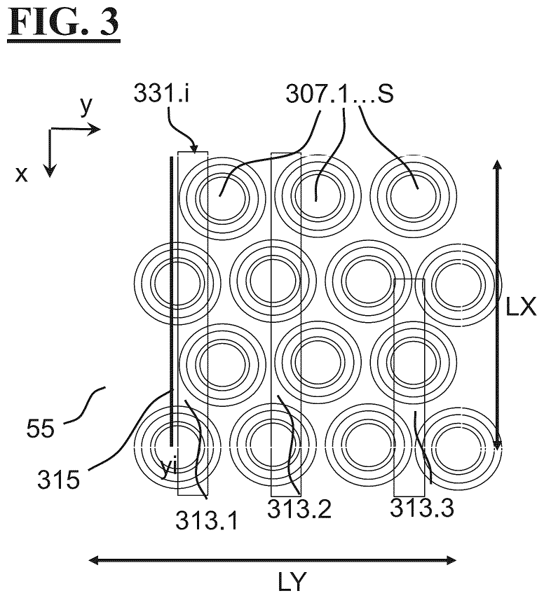

FIG. 3 shows an averaged image slice 331.i generated by the imaging charged particle beam 44 and corresponding to the ith cross-section surface 53.i. The averaged image slice 311.i comprises an edge line 315 between the slanted cross-section and the surface 55 of the wafer at the edge coordinate yi. Right to the edge, the averaged image slice 331.i shows several cross-sections 307.1 . . . 307.S through HAR structures which are intersected by the cross-section surface 301.i. In addition, the averaged image slice 331.i comprises cross sections 313.1 to 313.3 of several word lines at different depths or z-positions. According to the first embodiment, a method of image formation of a stack of M averaged image slices with increased throughput and accuracy is provided. A data stack of M high quality averaged image slices is determined from mean values of the first plurality of N cross section images. According to the first embodiment, less image scanning time is used for the acquisition of each cross-section image and many cross-section images are generated, each having a higher noise level. High quality averaged image slices are generated by averaging over subsets of cross-section images with a convolutional kernel. The method of image acquisition of a stack of M averaged image slices according to the first embodiment relies on the typical property of semiconductor objects of interest, for example HAR channels, which are expected to change in a predetermined direction only slightly. By computing a moving mean value or average in the predetermined direction over many cross-section images, noise is effectively reduced and a time for image acquisition can be reduced. Furthermore, the milling time for the generation of cross sections is more effectively used for generation of even more and denser cross section images with smaller distance between the cross sections.

The method according to the first embodiment is insensitive to errors during the milling and imaging process. Less image scanning time is used for the acquisition of each cross-section image and many cross-section images are generated, from which averaged image slices are computed. For each new image scan, any milling artefact of a previous cross section image is removed, and defects or artefacts of the milling operation may change from cross section surface to cross section surface. According to the first embodiment of the disclosure, at least some of these milling artefacts are averaged out with the formation of the moving average, and a polishing of cross section surfaces is not required any more. The depth of field of a charged particle beam imaging system is quite low and a perfect focus is hard to achieve. By averaging over a plurality of cross section images, focusing defects of individual cross-section images are averaged and averaged image slices of higher definition are generated, and a time-consuming precision focus adjustment can be omitted.

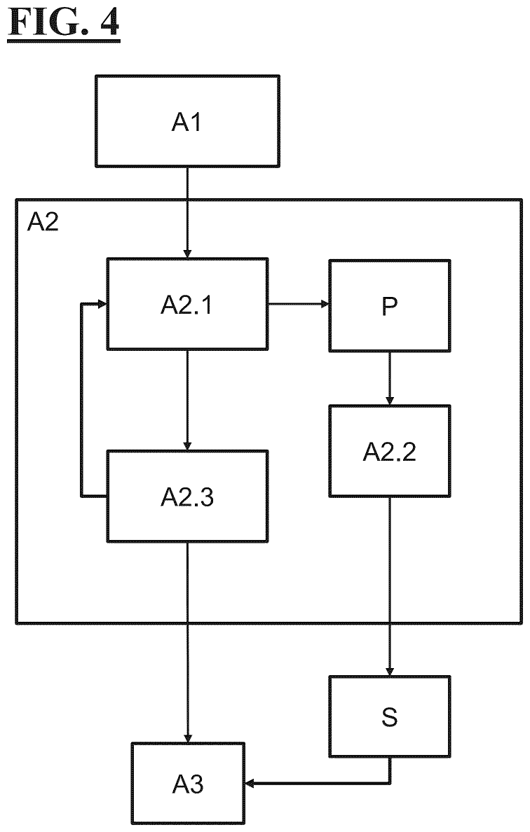

A method according the first embodiment is illustrated in FIG. 4.

In Step A1, an inspection site 6.i is selected and positioned and hold at the intersection point 43 of the dual beam device 1. An inspection volume 160 is defined and processing parameters for the acquisition of a 3D volume image are defined. The parameters comprise for example the number Q of cross section surfaces to be milled, the number N of cross-section images to be acquired, and the size or extension B of a 1D convolution kernel and the predetermined direction, in which the 1D convolution kernel is to be applied. Further parameters are the dwell time and other parameters of the image acquisition used for the acquisition of the cross-section images. The parameters may further comprise thresholds for interrupting or discontinuing the method.

In Step A2, the slice- and image method is performed until a threshold is reached. A threshold can be reached if a predetermined control condition is met, for example a certain depth within the semiconductor wafer sample or an appearance of a certain layer within the volume of interest within the semiconductor wafer sample.

In step A2.1, the number of cross section surfaces is milled by the FIB, the number N of cross-section images is acquired by the charged particle beam imaging system. The cross-section images are stored in memory P.

In optional step A2.3, a repeated assessment is performed whether the inspection volume boundaries have been reached or whether the desired information has been collected. If a predefined threshold is reached, the slice- and image method is discontinued.

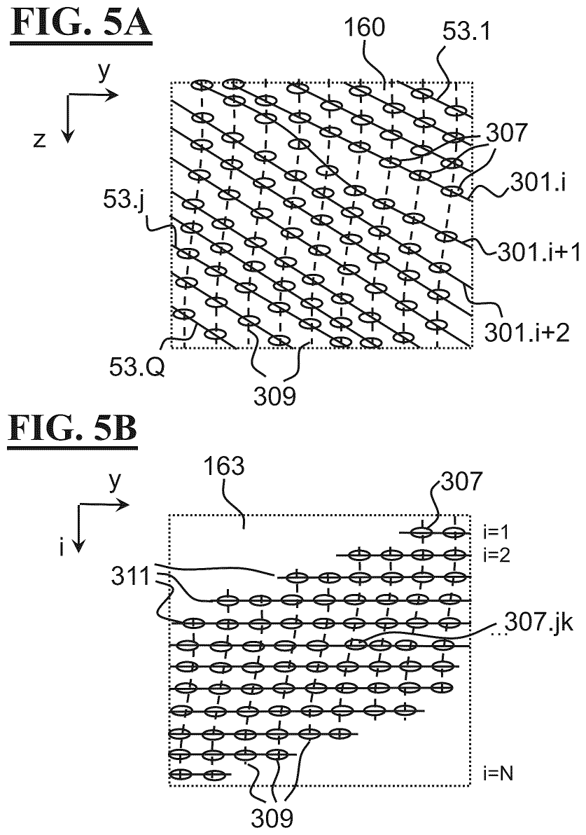

The result is illustrated in FIGS. 5A-5B at the example of HAR channels in a 3D-memory stack. FIG. 5A shows a plurality of cross section surfaces 53.1 to 53.N at a slanted angle GF through an inspection volume 160 with a plurality of HAR structures 309. Each cross-section surface intersects a plurality of HAR structures with cross sections 307. FIG. 5B illustrates schematically the image data stack 163 in memory P with the plurality of cross-section images 311.1 to 311.N, each cross-section image 311.i corresponding to the image acquired from one of the N cross-section surfaces 53.1 to 53.N. Each cross-section image 311.i is for example aligned after a first alignment at fiducials or alignment marks (not shown) or by a precision stage.

In step A2.2, a sequence of subsets of cross section images 311.1 . . . . N is processed, and an average averaged image slice is computed from each subset of cross section images. During the processing, moving average values of each subset of cross section images are computed.

The formation of the M averaged image slices can be described as a mathematical convolution of a 3D data image stack of cross-section images with a 1D-convolution kernel. In an example, the large number N of cross-section images form a 3D data set with transversal coordinates x and y of each image, and the different z-coordinates are corresponding to the predetermined direction. The moving mean value or average is described by a convolution with a 1D convolution kernel over the z-coordinate of the 3D data stack. The convolution kernel can be a function over a predetermined number of cross section images, for example a moving rect-function or a moving gaussian kernel in z-direction. Other convolution kernels for computing different weighted moving averages point wise median filters are possible as well. Other examples of convolution kernels are corresponding to filters for finding a minimum of a norm or matching function according to a given noise model. The width of the convolution kernel can be determined during step A1 or can be adaptive in accordance with a local noise level or a desired SNR of an averaged image slices. For example, if a noise level is too high, the extension B of the convolution kernel can be increased. The method is however not limited to classical computation of the convolution with a convolutional kernel, but instead machine learning based algorithms may be applied the optimally perform the computation of the averaged image slices.

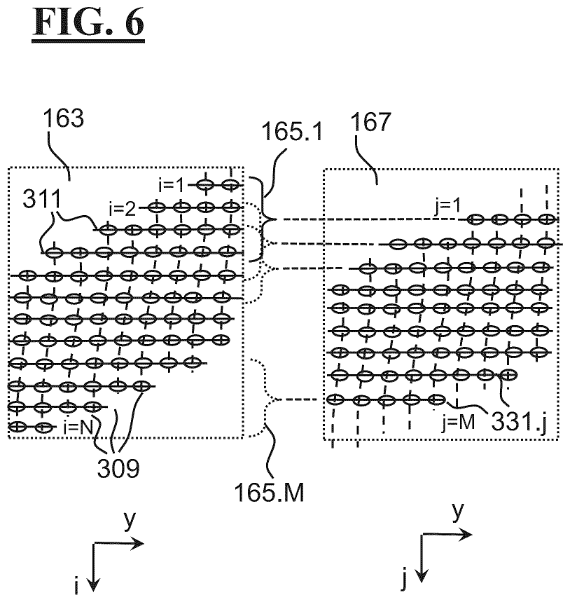

FIG. 6 illustrates a first example of the method step A2.2 at the example of FIG. 5. For a first subset 165.1 of four cross section images with i=1 to I=4, an average value is computed and a first averaged image slice 331.1 with j=1 is written into a memory S. Then, the averaging continues with a second subset 165.2 of four cross section images with i=2 to i=5, and a second averaged image slice 331.2 with j=2 is written into the memory S. By iterating the method step until the last subset 165.M, finally a data stack 167 of averaged image slices comprising j=1 to M averaged image slices 331.j is generated in memory S.

In step A3, the semiconductor object of interest in the inspection volume is investigated and parameters of the semiconductor object of interest are determined. For example, the semiconductor object of interest is formed by a plurality of repetitive semiconductor structures, such as the HAR structures shown in FIG. 2. The parameters can for example be a volume, a lateral position, a dimension such as a distance or diameter, an overlay area, an average value of these features, and a maximum deviation from an average value of an individual structure. The parameters or features of interest are finally attributed to the inspection site and stored in the memory S of the control unit 2 or written to an inspection file.

The generation of the data stack 167 of averaged image slices 331.1 . . . . M according to step A2.2 can be obtained according to different examples. In the first example according to FIG. 6, a moving average is determined, and a large number M of averaged image slices is generated. This operation is equivalent to a mathematical convolution in direction of the index i of the data stack 163 of cross section image 311.1 to 311.N. The convolution kernel can be a weighted sum of the image intensities of each set of cross-section image 311 for a given coordinate (x,y). The weights can be equal or different. Examples of convolution kernels are given by a rect-function (with equal weights) or a gaussian function. The width of a convolution kernel, i.e. the number B of each subset of cross section images, over which an average value is computed, can be B=3 or more, such as more than 9 or 11. Larger numbers are also possible, for example with an B about 50 or more. By increasing the extension of the averaging convolution kernel, the time for fast image acquisition can even be more reduced and the throughput can be even more enhanced at no increase of image noise in the averaged image slices.

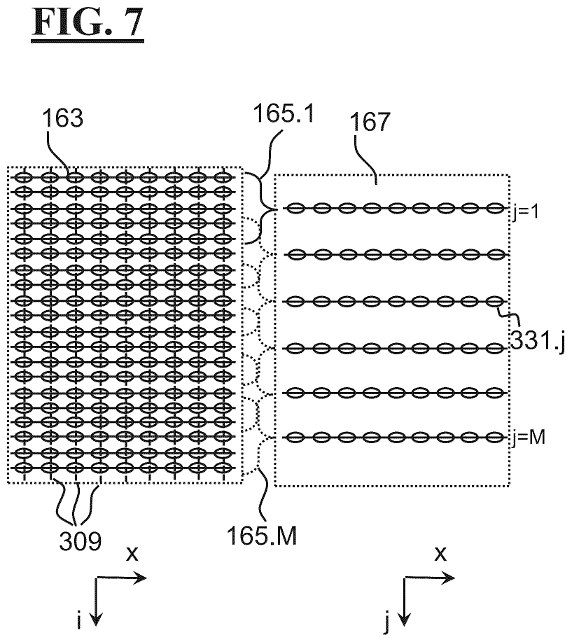

FIG. 7 illustrates another example. Here, the number M of averaged image slices 311 is further reduced by performing the averaging operation only for every second, every third, or generally every nth subset of cross-section images, with the example of a number n=4 in FIG. 7. Here, the extension of the averaging convolution kernel is illustrated with B=5, and each averaged image slice 331 is computed from a subset 165.j of B=5 cross section images from the data stack 163. In examples, the number B can be higher. The averaging convolutional kernels of this example still have an overlap over the cross-section images slices from the data stack 163, such that the data from some cross section averaged image slice is used for the computation of two different averaged images slice 331.j. In such an example, the convolution kernel can be a weighted sum with unequal weights, such as a symmetrical triangle function or a Gaussian function.

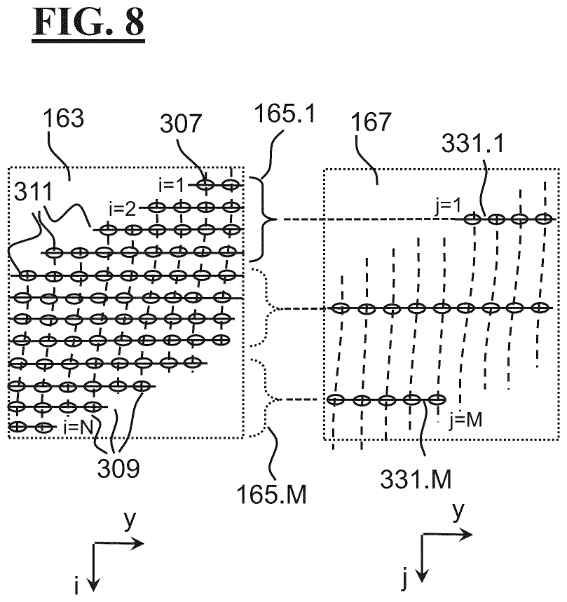

FIG. 8 illustrates a further example. Here, the number M of averaged image slices is even further reduced, and the subsets of cross section images for computing the averaged image slices don't show any overlap anymore.

Throughout the examples, it is not necessary to acquire the full data stack 163 of cross-section images 311.1 . . . . N at once; in an example the computation of averaged image slices 331.1 . . . . M is performed in parallel the image acquisition, and not all cross-section images 311.1 . . . . N is kept in the memory P. Once a moving average averaged image slice 331.j is computed, the cross-section images 311.i not required anymore can be overwritten by new cross section images. Thereby, the memory size of memory P can be limited.

In an example, the number of M of averaged image slices is approximately equal to the number of N of cross section images, and the number of M of averaged image slices is derived from an averaging convolution kernel with extension of B. In another example, the number of M is significantly smaller compared to the number of N of cross section images, with M<=A×N; with a factor A>=3, for example A=5, A=7 or A=20 or more.

In the examples above, a cross-section averaged image slice 311.i is obtained from each cross-section surface 53.i by fast scanning image acquisition. It is however also possible that the number N of cross-section averaged image slices 311.1 . . . . N deviates from the number Q of cross-section surfaces 53.1 . . . . Q. For example, the number N of cross section images is typically between a number Q of the plurality of cross section surfaces 53 divided by two and two times the number of cross-section surfaces 53, with 2×Q=>N=>Q/2. For example, a fast milling is applied, and the fast image acquisition is applied only every second cross section surface, with N<Q. For example, each cross-section surfaces 53.1 . . . . Q is imaged at least once by a fast-scanning operation with the charged particle beam imaging device 40 and for each cross-section surface 53.1 . . . . Q, at least one cross-section image 311.1 . . . . N is obtained, with N>Q.

Between each subset of the cross-section images of cross section surfaces at small milling distance, changes of the semiconductor object of interest are typically very limited. In an example, a plurality of cross-section surfaces 53.1 . . . . Q is milled by FIB 50 through an inspection volume 160 with a small z-distance of for example below 5 nm, 3 nm or even below 2 nm. By acquisition of a large number N of cross-section images 311.1 . . . . N of different cross-section surfaces 53.1 . . . . Q formed in the inspection volume 160, a drift of the stage 155 or a charged particle beam imaging column 40 can be determined from the cross-section images 311.1 . . . . N and effectively removed during the computation of the moving mean or average value by determining best matching conditions of a subset of cross-section images. In an example, an image contrast of an averaged image slice 331.j is evaluated for example by computing gradients. If an overall low gradient or low contrast is detected in a specific direction, the determination of the mean value is optimized by including lateral shifts to the cross-section images of the subset of cross-section images. Thereby, the effect of a drift in that specific direction is reduced. During an optimization of the drift compensation, the maximum expected drift may be limited to reduce computational time and increase robustness of the method. A drift can be determined as an absolute drift of each cross-section image relative to a reference, or as a relative drift to for example a previous cross-section image. Different registration or alignment methods may be employed to enhance the speed and performance of the drift compensation. In certain instances, manual verification of a drift compensation is possible and wrong image shifts can be discarded.

According to the first embodiment of the disclosure, a large number of N cross section images is obtained with reduced scanning times, and therefore increased noise level. The stack of M averaged image slices is formed by averaging. Thereby, the increased noise level of the quickly acquired cross section images is reduced and averaged image slices with increased SNR are formed.

During the determination of a moving average, global drifts can be detected and compensated, while individual deviations of the trajectories of for example HAR channels can still be detected. Further alignment and registration of the cross-section images at fiducials of image features is possible as well. The computation of the averaged image slices can be performed during the image acquisition according to the slice and image method, and thereby the memory demand for storing the plurality of N cross section images is reduced.

The method according to the first embodiment can further be applied to generate training data for an inspection method using machine learning. Annotation can be transferred from averaged image slices of low noise level to the set of cross-section images used for the averaging, each with large noise level and acquired by fast image scanning. It is thus possible to annotate with high precision at the high-quality averaged image slices and to transfer the annotation information to the set of cross-section images for training a machine learning algorithm to extract information from cross-section images with large noise level, obtained by fast image scanning.

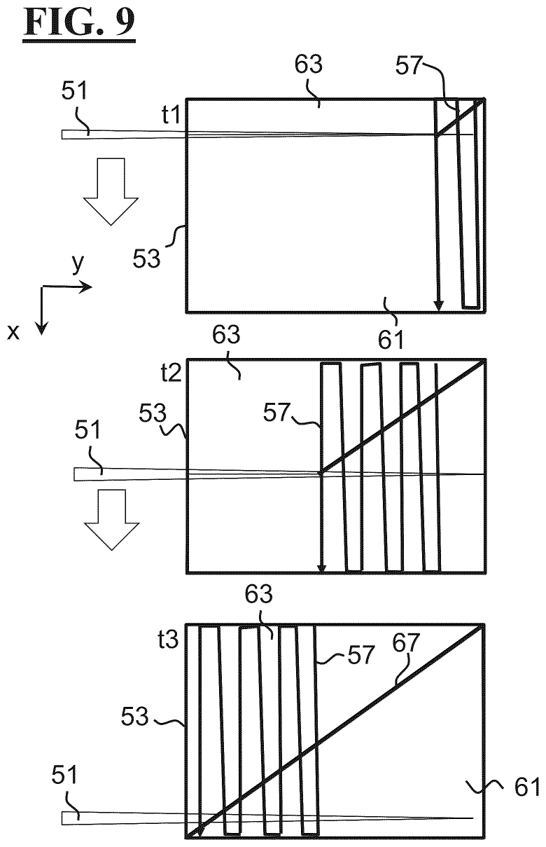

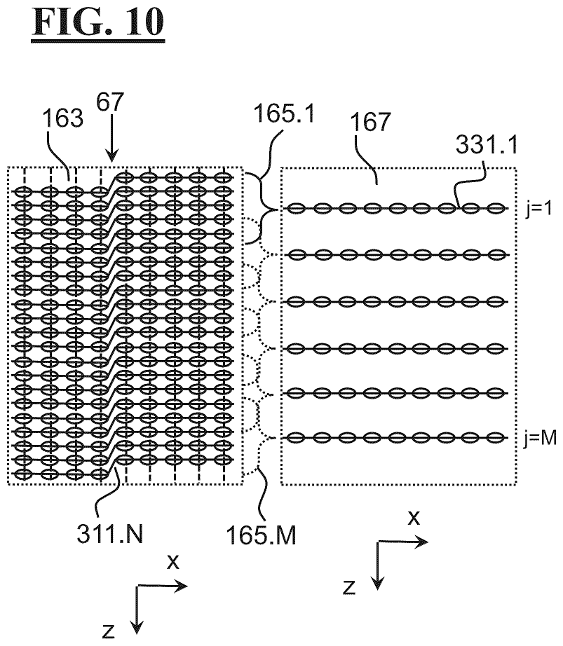

Impacts of drifts are even further reduced according to a second embodiment. According to the second embodiment, the image acquisition of N cross-section images and the milling of N cross section surfaces are performed in parallel at the same time. In an example, the milling by a FIB is performed by scanning the FIB beam 51 along a first direction (e.g. the x-direction). At the same time, an image acquisition is performed by scanning the imaging charged particle beam 44 across the cross-section surface in the same x-direction and by stepping from line scan to line scan in y direction. FIG. 9 shows the interlaced milling and image acquisition at three different times during the milling operation. At a first time t1, only a small fraction of the cross-section surface 53 is milled by FIB 51, and the image scan 57 is starting at the rear end of the milling operation by scanning in x-direction and stepping in y-direction. The image scan at time t1 is thus performed to a large part over the previous cross section surface 61 before milling. At a second time t2, approximately half of the next cross section surface 63 is milled, and the image scan 57 is performed over the previous cross section surface 61 as well as the newly milled cross section surface area 63 after milling. At time t3, the milling by Fib 51 is almost completed. Thereby, each cross-section image 311 of each interlaced milling- and imaging operation comprises a first area 61 according to a cross-section surface before the actual milling operation and a second area 63 according to a cross-section surface after the actual milling operation. The areas of different z-position are separated by a line 67. Each cross-section image 311 therefore comprises image areas of different z-positions. The large number N of cross-section images form again a 3D data stack with transversal coordinates x and y of each image, and the different z-coordinates corresponding to the two areas within each cross-section images. Thereby, an impact of a drift between different cross section images can even further be reduced. The method according to the second embodiment can be combined with the method according to the first embodiment, and a stack of M averaged image slices can be formed by determining a moving mean value or average as described in the first embodiment and illustrated in FIG. 10 by same reference numbers. An example is illustrated in FIG. 10. The moving average or mean value for an averaged image slice 331.m of the data stack of averaged image slices 167 is formed from a subset 165.m of cross-section images of the data stack 163 of cross section images 311.1 . . . . N. According to an example, a subset 165.m of cross-section images comprises also only parts of cross-section images 311.1 . . . . N which are within a specific z-range of the convolution kernel for the computation of a specific averaged image slice 331.m.

According to an example, it is possible to selectively add further cross-section images by for example a repeated image scan. For example, a first set of cross-section images can be obtained parallel to a milling operation as described in the second example, and a second set of cross-section images can be obtained between two subsequent milling operations.

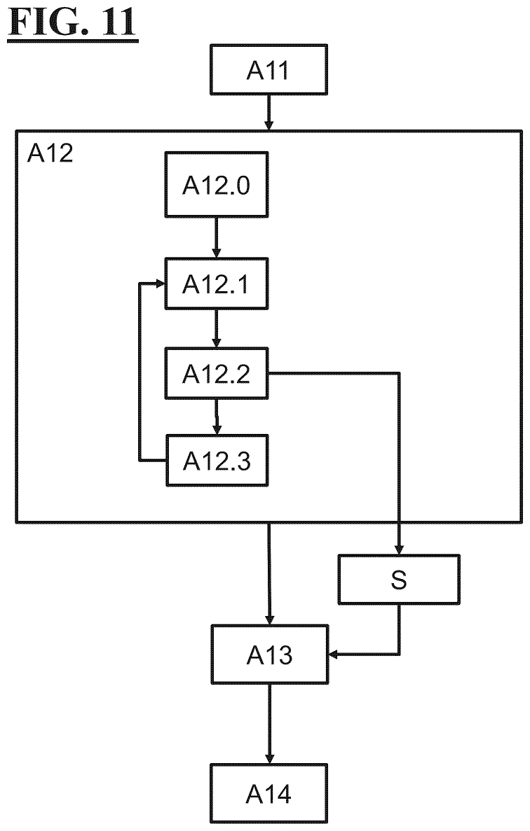

According a third embodiment of the disclosure, the throughput of the method for inspection of a 3D semiconductor object of interest in an inspection volume of a wafer sample can further be improved by limiting the performance of the time-consuming image scanning operation to selected regions of interest. A method according the third embodiment is illustrated in FIG. 11.

Step A11 follows the step A1 according the first example. In addition to step A1 of the first embodiment, a volume of interest within the inspection volume of a wafer sample is selected. The selection can be performed by external input, for example from CAD data, or by user input from for example a graphical user interface. For example, a user selects a volume of interest which comprises at least one semiconductor objects of interest. Step A11 can further comprise an adjustment of distances of cross section surfaces according to the selected volume of interest.

In Step A12, the slice- and image method is performed until a threshold is reached.

In optional step A12.0, a first cross-section image is acquired and an intersection of the volume of interest with the first cross-section image is determined. Thereby, the position of the volume of interest is registered.

For the determination and selection of the volume of interest, some “reference” structures of a semiconductor object within the first cross-section image can be used, for example the number of word-lines or other layers (see FIG. 2), or other significant features. The determination of the volume of interest can also comprise the identification of specific features (e.g., a transistor, a contact spot, an intersection of two or more elements) using a machine learning detection. The determination may further be improved by using fiducial or alignment marks.

In step A12.1, a next cross-section surface is milled by the FIB, and a region of interest is determined according to the intersection of the cross-section surface with the volume of interest.

In step A12.2, a cross-section image is obtained by image scanning of the region of interest with the charged particle beam imaging system. The cross-section image of the region of interest within the volume of interest is analyzed and optionally, the volume of interest is adapted for the next image acquisition step. Optionally, the image scanning of the cross-section image of an amended region of interest within the actual cross-section surface is repeated. The final cross-section image of the region of interest of the actual cross-section surface is stored in memory S.

In optional step A12.3, an assessment is performed whether the boundaries of the volume of interest have been reached or whether the desired information has been collected. If a predefined threshold is reached, the slice- and image method is discontinued.

In step A13 follows the step A3 according the first example, with the difference that the investigated and determination of parameters of the semiconductor object of interest is limited to the selected volume of interest.

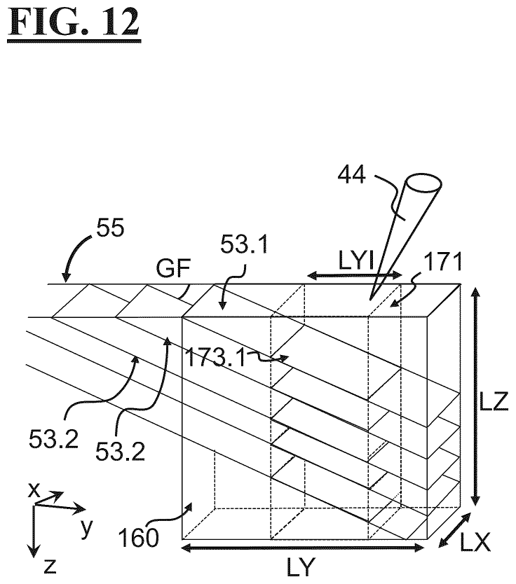

An example of a limited image acquisition is schematically illustrated in FIG. 12. A plurality of cross section surfaces 53.i inside an inspection volume 160 is illustrated, which are subsequently milled by the FIB under angle GF to the surface 55 of a wafer.

The inspection volume has an extension of LX×LY×LZ. Inside the inspection volume 160, a volume of interest 171 is determined. In this simplified example, the volume of interest has an extension of LX×LYI×LZ. In this example, the charged particle imaging beam 44 of the imaging system is arranged perpendicular to the cross section surfaces 53 (or perpendicular to the FIB axis 48, see FIG. 1). Thereby, a higher resolution can be achieved during imaging. The acquisition of cross section images by the charged particle imaging beam 44 is limited to the regions of interest 173.i of each cross section surface 53.i (only the first regions of interest 173.1 is indicated). The extension of the region of interest in y-direction is thereby limited to LYI, which is significantly smaller than L. The image scanning of the charged particle imaging beam 44 is adjusted for each cross-section surface 53.i, and a time interval for image acquisition is reduced.

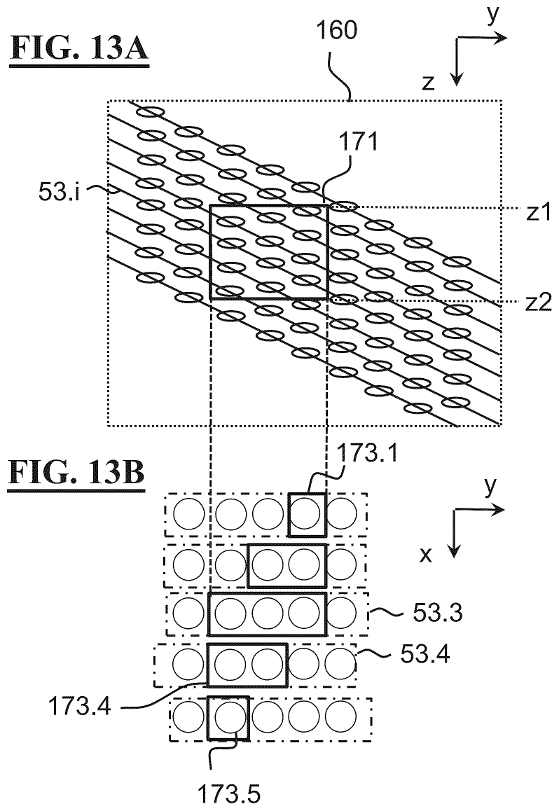

FIG. 13A illustrates an example of a buried volume of interest for the investigation of HAR channels. Here, the volume of interest is limited by two z-planes z1 and z2 and is limited to comprise 3 HAR channels. FIG. 13B shows the top view of five consecutive cross-section surfaces 53 and the corresponding regions of interest 173.1 to 173.5. A time interval for image acquisition is reduced. In an example, a lateral drift may happen for example between milling of cross section surface 53.3 and 53.4, which is no concern, since a region of interest 173.4 can be adjusted to compensate any lateral drift accordingly.

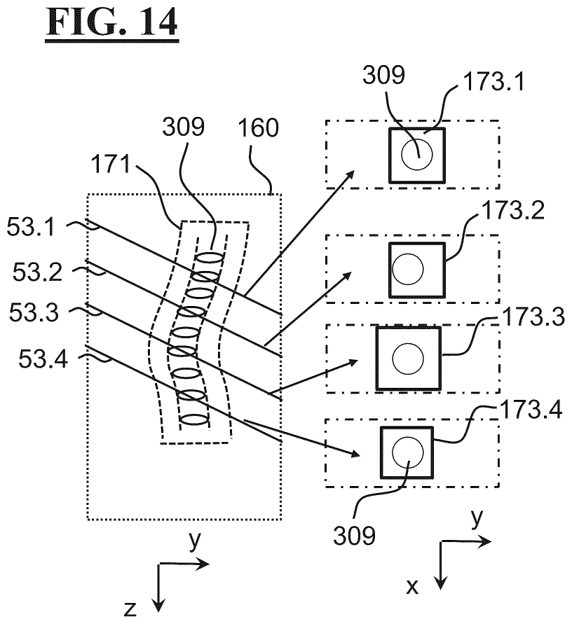

FIG. 14 illustrates an example of a frequent or dynamic adjustment of the regions of interest 173 to cover a volume of interest 171 inside an inspection volume 160. The volume of interest of this example is dynamically adjusted in step A12.2 to cover a semiconductor object of interest, for example a HAR channel 309. In a first cross section surface, 53.1, a first region of interest 173.1 is determined to cover the semiconductor object of interest (here, a cross section through HAR channel 309). The region of interest 173.1 is selected to comprise the cross section through the HAR channel 309, with a certain border area to cover an expected lateral position change of the HAR channel 309. The second region of interest 173.2 is then selected according the first region of interest 173.1, and the image slice of the second cross section surface 53.2 is analyzed, for example by image processing methods or pattern recognition methods. In the example, the cross section through HAR channel 309 is not in the center of the second region of interest 173.2 anymore, and the subsequent region of interest 173.3 is adaptively changed to a larger extension and a new center position at the center of the cross-section through HAR channel 309 in region of interest 173.2. After analyzing the cross-section through the HAR channel 309 inside the image acquired from region of interest 173.3, a size of a subsequent region of interest 173.3 can be reduced again, for example if the cross-section through the HAR channel 309 in cross-section surface 53.3 has not changed relative to the cross-section through the HAR channel 309 in cross-section surface 53.2. By iteratively adjusting size or position of the regions of interest 173 from slice to slice, the time-consuming operation of the scanning image acquisition can be reduced.

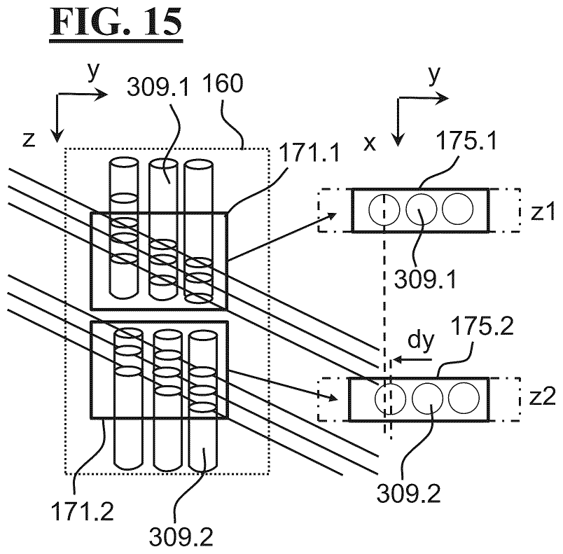

FIG. 15 shows another example of the third embodiment with two volumes of interest 171.1 and 171.2. In some applications, the relevant information to be extracted by an inspection task is a spatial relationship between two semiconductor objects of interest 309.1 and 309.2 within an inspection volume 160. In the example, a first averaged image slice 175.1 of a first region of interest of the first volume of interest 171.1 and a second averaged image slice 175.2 of a second region of interest of the second volume of interest 171.2 is generated, and a spatial relationship between the semiconductor objects of interest 309.1 and 309.2 can be determined. In this example, the spatial relationship is an alignment or overlay accuracy dy of two stacks of HAR channels 309.1 and 309.2.

According to an example, the method according the third embodiment comprises the further step A14 (see FIG. 11), according to which the measurement result is displayed to a user via a user display. The measured image data stack is displayed inside the inspection volume, and the missing image information from outside the volume of interest is augmented by for example CAD information.

With the third embodiment, an inspection method with increased throughput is provided, including an automatic adjustment of the milling and imaging parameters during the slice-and-imaging method which allows one to obtain the data-stack of image slices optimized for a particular inspection task, for example searching for particular defects, focused on particular IC-elements or their parts or on a particular location inside a semiconductor wafer. The adjustment of the imaging parameters includes the limitation the scanning image acquisition to the cross-section surface segments within the at least one volume of interest, while the faster milling might form larger cross-section surfaces. In an example, the image acquisition is performed inside the volume of interest with a high resolution and a long dwell time, and the image acquisition is continued outside the volume of interest with a low resolution and a short dwell. Thereby, a low-resolution overview image of the inspection volume, including the high-resolution volume image of the volume of interest is generated. The low-resolution overview image can be enhanced by augmented information according to step A14.

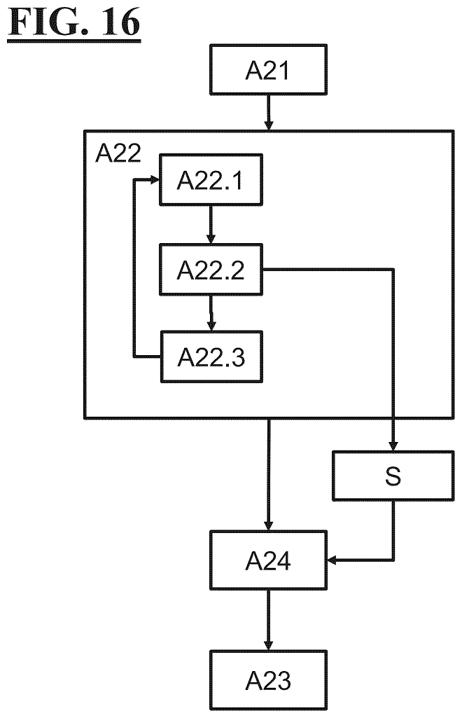

The third embodiment can be combined with the methods according the first or second embodiment, or with both. Thereby, an inspection method with even more increased throughput is provided. The reduction of the time interval for image acquisition according the third embodiment benefits from constraining the image acquisition to a small volume of interest within an inspection volume. In some examples, however, such a containment of a volume of interest is not possible. A method according to the fourth embodiment of the disclosure overcomes the issues of a volume image acquisition of a large volume of interest. According to the fourth embodiment, a method of sparse image acquisition is applied. A method according the fourth embodiment is illustrated in FIG. 16.

Step A21 follows the step A11 according the third example. In addition to step A11, step A21 further comprise selection of a density of sparse images to be acquired. For example, a sparse image acquisition can be performed for only less than 10% of the cross-section surfaces within an inspection volume. For example, a sparse image acquisition can be performed for about 30% or 50% of the cross-section surfaces within an inspection volume.

In step A22, the slice- and image method is performed until a threshold is reached. In step A22.1, a first or next cross-section surface is milled by the FIB.

In step A22.2, a first or next plurality of sparse image regions for sparse image acquisition is acquired from the cross-section surface milled in step A22.1. The sparse images are stored in memory S.

In step A22.3, the image regions are registered, and a next plurality of sparse image regions is determined. The determination can be obtained from the registered plurality of image regions such that, for example, an average distribution of sparse image regions over the inspection volume can be maintained. Thereby, a coverage of the inspection volume with image regions is maintained. The sparse image regions can also be determined from prior information, for example CAD information, and can be determined to cover special features of interest within the inspection volume.

In step A24, the 3D volume image of the inspection volume is computed from the sparse image data obtained in step A22. The computation can be performed by mathematical methods or by a machine learning method, which is trained to fill in missing data to complement the sparse image data. Mathematical methods can comprise interpolation, extrapolating or averaging. In another example, the missing data to complement the sparse image data is obtained from CAD information. For example, the 3D volume image can be derived by fitting of a parametric model description of the semiconductor object of interest to the sparse image data.

In step A23 follows the step A3 according the first example.

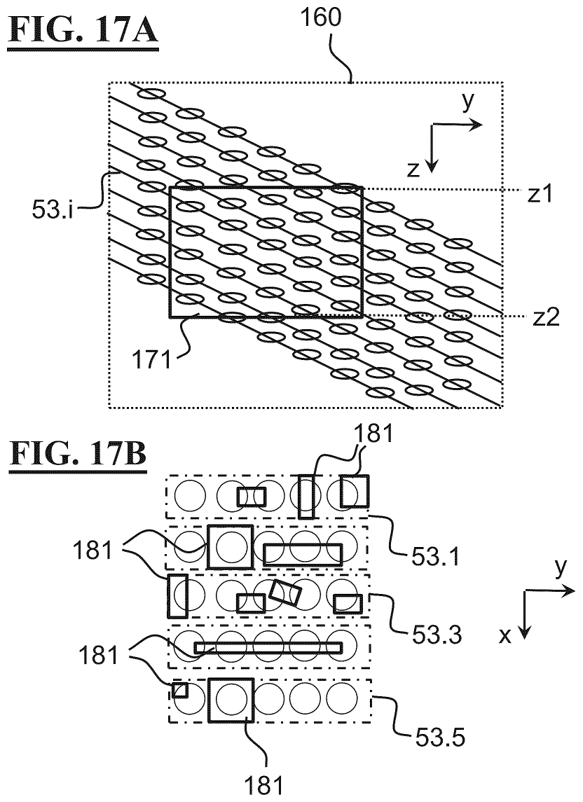

The fourth embodiment can be combined with the methods according the first to third embodiment. FIG. 17A illustrates an example of the method according the fourth embodiment. Inside of an inspection volume 160, a large volume of interest 171 is defined. A plurality of cross section surfaces 53 is milled (only one indicated). FIG. 17B illustrates five cross-section surfaces 53.1 to 53.5 in lateral x-y-coordinates. For each cross-section surface, different sets of sparse imaging regions 181 are defined and sparse image segments are acquired by the charged particle imaging beam. From the differently distributed sparse image segments, the 3D volume image of the volume of interest is extrapolated as described above in step A24.

One drawback of the slice- and image method is the destruction of the wafer sample inside the inspection volume 160. After a cross-section surface has been milled by removing the material above the cross-section surface, it is not possible to acquire additional images of the removed region in the inspection volume. This can be challenging in some examples of the embodiments of the disclosure. The fifth embodiment of the disclosure overcomes some of these issues of the fast image acquisition by utilizing a multi-modal imaging approach.

The method of the fifth embodiment employs a multi-modal image acquisition, comprising at least a first and a second imaging mode of operation of the charged particle beam imaging system for the image formation of the data stack of cross section images or of the averaged image slices. The images obtained by different imaging modes can be normalized, and averaged image slices can be computed as described in the first embodiment of the disclosure. In another example, different sparse image regions according the fourth embodiment can be obtained with different detector properties, and the signals obtained by a detector are adjusted to different semiconductor features. The images obtained by different imaging modes can supplement each other.

According to a first example, for the different imaging modes of operation, a detector property is adjusted. For example, during a first imaging mode of operation, a detector gain is adjusted to a low signal level, and during a second imaging mode of operation, a detector gain is adjusted to a high signal level. According to a further example, a cut-off energy of secondary or backscattered electrons is adjusted. Thereby, for example an imaging can be reduced to certain depths within a sample below a cross section surface or certain materials.

In an example, the method comprises a step of changing a detection mode between to subsequent image scanning operations, wherein a change of a detection mode comprises at least one of a change of a dynamic range, a change of an energy range of interaction products, or a change of a type of interaction products.

In an example, the accuracy of metrology tasks can be enhanced by extending the dynamic range of an image sample by acquiring a sequence of images in the same field of view. Each image in the sequence is acquired with different detector settings of a single detector. For example, with a given brightness/contrast (or gain/offset) setting for a detector, a specific range of charged particle counts can be measured by the detector. The charged particle count is converted by an analogue to digital converter into for example an 8 bit format. Thereby, differences of weak signals are lost due to the conversion loss.

On the other hand, if a detector gain is too high, strong signals generates a detector overflow and differences in strong signals are lost as well. To extend the minimum and maximum range of electron counts for the detector, the offset and gain can be adjusted so that different ranges of signals can be detected with high resolution. Thereby, an extension of the signal resolution of the SEM is achieved.

According to a second example, the different imaging modes are achieved in parallel by utilizing spatially separated or different detectors. For example, a first detector and a second detector can be arranged in different angular segments and be configured to determine a topography contrast. For example, a first detector can be configured to collect large angle scattered electrons, and a second, in-lens-detector can be configured to collect small angle backscattered electrons. For example, a first detector can be an electron detector and a second detector can be an X-ray detector. For example, a first detector can be configured to detect low energy interaction products, and a second detector can be configured to detect high energy interaction products. Interaction products can be secondary electrons or backscattered charged particle of the charged particle beam imaging system. With the second example with a first and a second detector, the desired information about the semiconductor object of interest and the accuracy of the image formation is further improved at no reduction of the throughput improvements according to the first to fourth embodiments.

With the multi-modal image acquisition, the image formation of a stack of M averaged image slices is further improved by obtaining additional information. The method according to the fifth embodiment can be combined with the methods according to any of the first to fourth embodiments.

An inspection system for 3D inspection of a semiconductor object of interest is described in the sixth embodiment of the disclosure. FIG. 1 shows a first example of an inspection system 1000 for 3D inspection in an inspection volume of a wafer sample 8. The inspection system 1000 is configured for performing the methods according to any of the first to fifth embodiment. The inspection system 1000 comprises a wafer sample holder 15 and stage 155 for holding and positioning the wafer sample 8. The inspection system comprises a dual beam device 1 comprising a FIB column 50 and a charged particle beam imaging system 40, for example a scanning electron microscope (SEM) or a Helium ion microscope (HIM). The dual beam device 1 further comprises at least one detector 17.1 for secondary or backscattered charged particles. In an example, the dual beam device 1 further comprises at least a second in-lens detector 17.2 for acquiring a second signal in a multi-modal imaging operation according the fifth embodiment. The inspection system further comprises a control unit 19 to control the operation of the dual beam device 1. The control unit 19 is configured for providing instructions to a scanning unit of the charged particle beam imaging system 40. Thereby, an image scanning operation can be limited to regions of interest or sparse imaging regions according to the third or fourth embodiment of the disclosure. The inspection system 1000 further comprises an operating control unit 2 with a memory for storing software program code, operations instruction program code and a memory for storing the acquired digital image data received from the detectors 17.1 and 17.2. The operating control unit 2 further comprises a processor configured for performing the processing instructions for the computation of moving averages. The operating control unit 2 of the inspection system 1000 is further configured to receive prior information, for example CAD information, via an interface. Further details of the inspection system 1000 of FIG. 1 are described above.

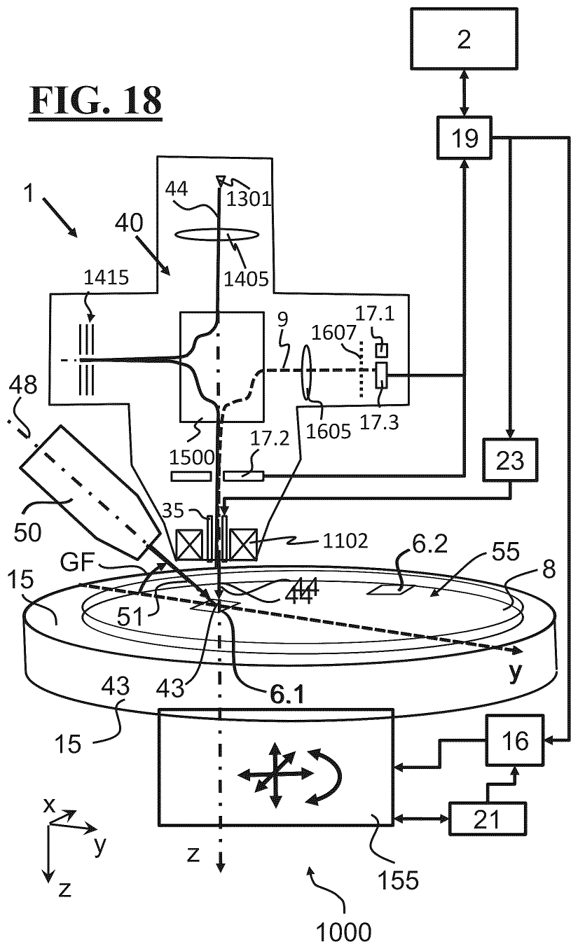

FIG. 18 shows a second example of an inspection system 1000 for 3D inspection in an inspection volume of a wafer sample 8. Same reference numbers are used as in the description of FIG. 1, and reference is made to the description of FIG. 1. In the second example, the charged particle beam imaging system 40 is formed by a corrected electron microscope with a plurality of detectors 17.1 and 17.3 for angular resolved imaging of interaction products is applied. Such a corrected electron microscope is described in international patent application PCT/EP2022/079753, filed on Oct. 25, 2022, which is incorporated herein by reference. The corrected electron microscope comprises an electron source 1301, a collimation system 1405, a beam divider 1500, a mirror element 1415. With the mirror element 1415, chromatic aberrations as well as spherical aberration and field curvature are corrected. The corrected electron microscope 40 further comprises an in-lens detector 17.2 and an objective lens 1102 with a deflection scanner 35. Backscattered and secondary electrons 9 are collected by the objective lens 1102 and at least partially guided via the beam splitter to a projection system 1605 to electron detectors 17.1 and 17.3.

The FIB column 50 and the charged particle beam imaging system 40 of the dual beam device 1 are arranged at an angle and forming an intersection point 43 of the optical axes 48 and of the columns. The stage 155 is configured for positioning and holding a wafer sample 8 comprising an inspection volume in proximity to the intersection point 43.

According to an example, the charged particle imaging system of the dual beam device is configured for performing different imaging modes according to the fifth embodiment. Different imaging modes can comprise different detectors or detectors configured for different detector settings. A detector can comprise a grid 1607 with a variable grid voltage. Thereby, a detector setting can be changed by selection of a repelling field to cut off charged interaction products of low energy. A detector can comprise a variable analogue gain factor, configured for the adjustment of an analogue signal before conversion into a digital signal. Thereby, weak signals can be obtained with higher accuracy and detail. A detector can comprise several detector elements 17.1, 17.3 for angular resolved detection of interaction products. The charged particle imaging system 40 formed by a corrected electron microscope allows for an inspection with higher resolution at lower electron voltages of below 1 keV, for example below 500 eV or even below 300 eV.

A charged particle imaging system 40 according the sixth embodiment comprises a scanning deflector 35 and a scan controller 23, configured for performing different image scanning operations, for example including the performance of a line averaging, a variation of a dwell time, a variation of a scan path, for example a zig-zag scan strategy, or a meander scan strategy. The scan controller 23 is further configured for performing different image scanning operations according to the first to fourth embodiment of the disclosure. Different scanning configurations comprise a fast image scanning according to the first embodiment, an image scanning operation perpendicular to the FIB-beam 51 according to the second embodiment, a limited scanning operation, limited to at least one region of interest according to the third embodiment, or a limited scanning operation, configured for image scanning different sets of sparse imaging regions 181 according to the fourth embodiment.

An example of a charged particle imaging system 40 configured for performing different imaging modes according to the fifth embodiment comprise a source 1301 of charged particles and particle optical elements 1405 and 1102, configured for a variation of an acceleration voltage, a beam current, a charged particle beam angle, a numerical aperture of the charged particle beam, or a cross sectional shape of the charged particle beam. Throughout the description, the disclosure is described for the inspection within an inspection volume of a wafer sample. A wafer sample 8 can be formed by a wafer, for example a 300 mm wafer, of by a small wafer sample piece extracted from a wafer. A typical acquisition of an inspection volume with a lateral extension of about LX=10 μm×LY=10 μm and with a depth of LZ=10 μm involves slicing and imaging of for example 2000 cross section image slices with a dwell time of about 2 us per pixel. A typical time for the acquisition of a 3D volume image with high lateral resolution of about 2 nm can thus be more than 24 hours. Typically, image acquisition times are within 12 h and 30 h. The milling time for such an inspection volume, on the other hand, is about one hour or even less, almost irrespective of the number of cross-section surfaces to be milled. With the methods according to the embodiments of the disclosure, the time for image acquisition is significantly reduced, for example at least by a factor of two or more. For example, a dwell time is reduced by a factor of four and a SNR of cross-section image slice is improved by averaging over sets of cross-section images comprising at least four fast scanned cross-section images. Even if the number of cross section images is increased for example by a factor of two, the total time for image acquisition is reduced by a factor of two. The dwell time per pixel can even be further reduced, for example to below 0.1 μs, and the averaging kernel can be increased to cover for example 25 or 30 cross section images. Given the assumption of slowly varying semiconductor objects of interest in the predetermined direction (e.g. the z-direction perpendicular to the wafer surface), a minor resolution drop in the predetermined direction by averaging can often be accepted, and averaged image slices with large SNR are obtained. Thereby, a reduction of the image acquisition time be a larger factor is possible, for example a factor 5, 8 or even more. The noise level is indirect proportional to the dwell time (i.e. the square root of the dwell time), and by averaging over a set of cross-section images, at least a similar SNR of an image slice with a larger dwell time is achieved. Furthermore, fast image scanning with reduced dwell time per pixel is less sensitive to charging effects, and the SNR of averaged image slices is thus even more improved.

According to an example, a volume of interest is determined, and an image acquisition is limited to the regions of interest within each cross-section surface. According to another example, image acquisition is performed at sparse regions or segments of cross-section surfaces only. According to both examples, a time for image acquisition of high-quality cross-section image slices is reduced by a factor of two or more. In an example, the fast image acquisition and averaging is combined with limited regions of interest, and a time for image acquisition is even further reduced.

As described above, an image registration or alignment of the multiple images to be used for computing an averaged image is for example performed at a fiducial or alignment feature. Such an alignment feature can be a two-dimensional structure fabricated in advance by deposition of a metal layer and charged particle beam induced sputtering of an alignment feature in the metal layer. Such alignment features are typically of much larger extension of for example a line width of 20 nm or more, for example 50 nm, 100 nm or even more. Other examples of alignment features comprise existing features, present on semiconductor wafers, such as alignment markers. Other examples of alignment features comprise three-dimensional alignment features, such as line-structures, crosses or holes milled into a wafer.

Such larger extensions do not require an image acquisition at high resolution, compared to semiconductor features with dimensions of below 10 nm or even less, for example 5 nm, which typically involve an image resolution or sampling distance of 2 nm or less, for example 1 nm. Between each acquisition of a cross-section image, a drift may generate a lateral displacement between consecutive images. Even with coarse alignment features as described above, a lateral displacement from image to image can be determined with high accuracy of below 1 nm without sacrificing the speed of an image acquisition.

In a first example according to the first and second embodiment, within each quickly obtained cross-section image with larger noise level, an image of an alignment fiducial is obtained at the same, high resolution as the semiconductor features. In order to precisely compute a center position of the fiducial, the pixels covering the coarse fiducial can be averaged by a lateral convolution kernel. Thus, each image is locally averaged at an image region comprising the image data of an alignment fiducial, and a reference position of the image is obtained with high accuracy from the locally averaged image data of an alignment fiducial. With the lateral averaging, image noise is reduced, such that for example a center position of an alignment fiducial can be obtained with high accuracy. An averaged image of the semiconductor features is then obtained by averaging over several images with high lateral overlay precision.

In a second example according to the third embodiment, fast imaging is obtained by limiting the image acquisition to regions of interest. In a third example, a plurality of sparse image segments of semiconductor features of interest are obtained within each image scan. In addition to the image acquisition of a region of interest or the sparse image regions, an image region comprising an alignment fiducial can be included within each image acquisition. Thereby, the images of the regions of interest or the sparse image regions can be laterally aligned with high precision. In an example, a speed of an image acquisition is further increased by reducing the image acquisition time of an image segment of the alignment fiducial. As described above, alignment fiducials are typically large compared to semiconductor features of interest and do not require a high resolution.

Due to the statistical nature of noise, the time average and the ensemble average are identical. A low resolution image of an alignment fiducial can thus be obtained by fast scanning and lateral pixel binning or averaging as described above, or by changing the scanning image acquisition of the alignment fiducial to a lower resolution with either lower scanning frequency or averaging over several low-resolution images of the alignment fiducial.

The disclosure described by the embodiments can be described by following clauses:

Clause 1: A method of volume inspection of a 3D semiconductor object of interest in an inspection volume of a wafer sample, comprising:
acquiring a first number of N cross-section images by fast milling and fast image scanning of a plurality of cross-section surfaces through the inspection volume;
forming a second number of M averaged image slices from the first number of N cross-section images by computing moving average values in a predetermined direction of the semiconductor object of interest, wherein the moving average values for each average image slice are computed from a subset of the first number of N cross-section images.

Clause 2: The method according to clause 1, wherein the second number M is smaller than the first number N, with M<N, for example M<=A×N with a factor A>=3, for example A between 3 and 11, A=20 or even A about 50. Thus, for example, any of the following relations can hold: 3≤A≤11 or 3≤A≤20 or 45≤A≤55.

Clause 3: The method according to clause 1, wherein the second number M is almost equal to the first number N. For example, M<N and/or M/N≤0.95 or M/N≤0.98 or M/N≤0.99.

Clause 4: The method according to any of the clauses 1 to 3, comprising performing the fast milling of a new cross-section surface and the fast image scanning for the acquisition of a cross-section image subsequently at different times.

Clause 5: The method according to any of the clauses 1 to 3, comprising performing the fast milling of a new cross-section surface and the fast image scanning for the acquisition of a cross-section image in parallel at the same time, with a scanning direction of an charged particle imaging beam perpendicular to a direction of a focused ion beam (FIB), and wherein a cross-section image comprises a first area corresponding to a first cross-section surface before an actual fast milling operation and a second area corresponding to a second, deeper cross-section surface according to the actual fast milling operation.

Clause 6: The method according to any of the clauses 1 to 5, wherein the semiconductor object of interest is at least one HAR channel with the predetermined direction oriented perpendicular to a top surface of the wafer sample.

Clause 7: The method according to any of the clauses 1 to 6, comprising performing the fast milling at a slanted angle to a top surface of the sample, with a slanted angle GF equal to or below 45°, for example equal to or below 30°.

Clause 8: The method according to any of the clauses 1 to 7, comprising computing of moving average values over the second number of cross section images by convolution of the cross-section images with a one-dimensional convolution kernel parallel to the predetermined direction.

Clause 9: The method according to clause 8, wherein the one-dimensional convolution kernel is extending over at least B=3, such as between B=3 and B=20 consecutive cross section images, and having a form of a weighted sum, a rect function, or a gaussian distribution function. The following relation can hold: 3≤B≤20

Clause 10: The method according to clause 8 or 9, comprising selecting the extension B of the one-dimensional convolution kernel according to a noise level in the cross-section images, with a larger extension B of for example B=11, B=20 or more for higher noise levels, such that a predetermined Signal-to-Noise (SNR) level in an averaged image slice is obtained.

Clause 11: The method according to any of the clauses 1 to 10, comprising, during the computing of moving average values, compensating a lateral drift of a cross-section image of the plurality of cross section images, wherein the lateral drift direction is perpendicular to the predetermined direction.

Clause 12: The method according to clause 11, comprising determining the lateral drift of a cross section image in an averaged image slice according to a low gradient or low contrast in the drift direction, and optimizing the computation of the averaged image slice with maximum isotropic contrast or gradient by averaging and including lateral shifts to at least one cross-section image.

Clause 13: The method according to clause 11, further comprising determining the lateral drift from a reference position obtained from an image segment of an alignment fiducial.

Clause 14: The method according to clause 13, further comprising a laterally averaging by pixel binning or lateral convolution of the image segment of the alignment fiducial with an averaging convolution kernel.

Clause 15: The method according to any of the clauses 1 to 14, wherein the method further comprises a step of adjusting a distance between two adjacent cross-section surfaces according to prior information of the semiconductor object of interest within the at least first volume of interest.

Clause 16: The method according to any of the clauses 1 to 15, further comprising a step of adjusting a milling angle of a subsequently milled cross-section surface according to prior information of the semiconductor object of interest within the at least first volume of interest.

Clause 17: The method according to any of the clauses 1 to 16, further comprising a step of changing a detection mode between subsequent fast image scans, wherein a change of a detection mode comprises at least one of a change of a dynamic range, a change of an energy range of interaction products, or a change of a type of interaction products.

Clause 18: A method of inspection of a 3D semiconductor object of interest in an inspection volume of a wafer sample, comprising:
defining at least a first volume of interest in an inspection volume of a semiconductor wafer, the first volume of interest being withing the inspection volume;
milling a plurality of cross section surfaces through the inspection volume;
acquiring a number of cross section image segments by performing image scanning operations of cross-section surface segments withing the at least first volume of interest, wherein each cross section image segment is determined according a regions of interest formed by the intersection of a cross-section surface with the at least first volume of interest.

Clause 19: The method according to clause 18, comprising performing the milling at a slanted angle to a wafer surface and at least first volume of interest is oriented perpendicular to the wafer surface.

Clause 20: The method according to clause 18 or 19, comprising defining the at least first volume of interest according to CAD data.

Clause 21: The method according to any of the clause 18 to 20, further comprising the step of aligning the at least first volume of interest within the inspection volume according to at least a first image scan of a first cross-section surface within the inspection volume.

Clause 22: The method according to clause 21, wherein the step of aligning comprises further re-alignment of the at least first volume of interest at at least a second or further image scans of a second and further cross-section surfaces within the inspection volume.

Clause 23: The method according to any of the clauses 18 to 19, wherein the step of defining the at least first volume of interest comprises the steps of:
a) acquiring a first image scan of a first cross-section surface,
b) selecting a first cross-section image segment in the first image scan, the first cross-section image segment is including a cross section of a semiconductor object of interest,
c) milling of a second cross-section surface into the inspection volume of the wafer sample,
d) selecting a second cross-section image segment by projecting the first cross-section image segment onto the second cross-section surface,
e) acquiring a second cross-section image segment of the second cross-section surface segment.
f) repeating steps c) to e) by milling further cross-section surfaces, selecting and acquiring further cross-section image segments until a predefined interruption criterion is met.

Clause 24: The method according to clause 23, wherein, during step e), the projecting the first cross-section image segment onto the second cross-section surface is performed in the predetermined direction.

Clause 25: The method according to clause 23 or 24, further comprising the step of adjusting a position and size of the first cross-section image segment according the second cross-section image segment, wherein the position and size of the cross section of semiconductor object of interest within the second cross-section image segment is analyzed by image processing.

Clause 26: The method according to any of the clauses 18 to 25, wherein the semiconductor object of interest is a HAR channel and the predetermined direction is oriented perpendicular to a wafer surface.

Clause 27: The method according to any of the clauses 18 to 26, further comprising the step of generating a 3D volume image of the 3D semiconductor object of interest.

Clause 28: The method according to clause 27, wherein the step of generating a 3D volume image the inspection volume comprises the step of generating the 3D volume image of the at least first volume of interest and the step of generating an augmented 3D image data outside the at least first volume of interest.

Clause 29: The method according to clause 28, wherein the augmented 3D image data is obtained from CAD data.

Clause 30: The method according to any of the clauses 18 to 29, further comprising a step of adjusting a distance between two adjacent cross-section surfaces according to prior information of the semiconductor object of interest within the at least first volume of interest.

Clause 31: The method according to any of the clauses 18 to 30, further comprising the step of forming a number of image slice segments from the plurality of cross section image segments by determining a moving average along a predetermined direction.

Clause 32: The method according to any of the clauses 18 to 31, further comprising a step of changing a detection mode between two subsequent image scanning operations, wherein a change of a detection mode comprises at least one of a change of a dynamic range, a change of an energy range of interaction products, or a change of a type of interaction products.

Clause 33: A method of inspection of a 3D semiconductor object of interest an inspection volume of a wafer sample, comprising:
milling a plurality of cross section surfaces through the inspection volume,
selecting a plurality of sparse regions for each cross-section surface,
acquiring a plurality of sparse cross-section image segments by performing image scanning operations of the plurality of the sparse regions of each cross-section surface,
generating a 3D volume image of the inspection volume from the plurality of sparse cross section image segments.

Clause 34: The method according to clause 33, wherein the step of generating the 3D volume image comprises an image interpolation between the plurality of sparse cross-section image segments.

Clause 35: The method according to clause 34, wherein the image interpolation between the plurality of sparse cross section image segments is based on CAD data the 3D semiconductor object of interest.

Clause 36: The method according to clause 33, wherein the selection of the plurality of sparse regions of each cross-section surface changes from cross section surface to cross section surface.

Clause 37: The method according to any of the clauses 33 to 36, wherein the selection of the plurality of sparse regions of each cross-section surface is performed according to an image analysis of a previously acquired plurality of sparse cross section image segments.

Clause 38: The method according to any of the clauses 33 to 37, wherein the selection of the plurality of sparse regions is performed according to CAD data.

Clause 39: The method according to any of the clauses 33 to 38, wherein the milling is performed at a slanted angle to a wafer surface.

Clause 40: The method according to any of the clauses 33 to 39, wherein the method further comprises a step of adjusting a distance between two adjacent cross-section surfaces according to prior information of the semiconductor object of interest.

Clause 41: The method according to any of the clauses 33 to 40, further comprising a step of changing a detection mode between to image scanning operations, wherein a change of a detection mode comprises at least one of a change of a dynamic range, a change of an energy range of interaction products, or a change of a type of interaction products.

Clause 42: The method according to any of the clauses 33 to 41, further comprising compensating a lateral drift of each plurality of sparse regions of each cross-section surface.

Clause 43: The method according to clause 42, comprising determining the lateral drift from a reference position obtained from an image segment of an alignment fiducial.

Clause 44: The method according to clause 43, further comprising obtaining an image segment of the alignment fiducial with lower resolution.

Clause 45: A method of inspection of a 3D semiconductor object of interest an inspection volume of a wafer sample, comprising:
milling a plurality of cross-section surfaces through the inspection volume,
scanning each cross-section surface with an imaging charged particle beam image, wherein during the scanning, interaction products are generated, comprising secondary electrons, backscattered charged particles, photons or x-rays in different energy ranges,
forming a plurality of cross-section images from detection signals of at least a first and a second interaction product.

Clause 46: The method according to clause 45, wherein the first interaction product and second interaction product are selected according to either
a) a first and a second energy range of a selected interaction product, or
b) a first and a second dynamic range of a selected interaction product, or
c) a first and a second type of interaction products.

Clause 47: The method according to clause 45 or 46, wherein, during the step of forming the plurality of cross-section image, a cross-section image obtained from a first detector is enhanced by information received from a second detector.

Clause 48: The method according to clause 45 or 46, wherein, during the step of forming the plurality of cross-section image, a cross-section image obtained from a first image scan is enhanced by information received from a second image scan.

Clause 49: A semiconductor inspection device for inspection of 3D semiconductor objects of interest in an inspection volume of a wafer sample, comprising:
a wafer sample stage for holding and positioning a wafer sample;
a dual column microscope comprising a focused ion beam (FIB) column and a charged particle beam imaging column, forming a common intersection point of an optical axis of the FIB column and an optical axis of the charged particle beam imaging column,
a control unit configured to control the dual column microscope to perform an slice- and image method in the inspection volume,
a processor and a memory with software code installed, the processor being configured to perform any of the method steps above.

Clause 50: The semiconductor inspection device according to clause 49, further comprising at least a first and a second detector configured for performing a multi-modal image acquisition.

Clause 51: The semiconductor inspection device according to clause 49 or 50, wherein the charged particle beam imaging column is formed by a corrected electron microscope comprising correction means for correction of chromatic aberration and spherical aberration.

The disclosure described by examples and embodiments is however not limited to the clauses but can be implemented by those skilled in the art by various combinations or modifications thereof.

A list of reference numbers is provided:
1 Dual Beam Device
2 Operation Control Unit
4 cross section image features
6 measurement sites
8 wafer sample
15 wafer support table
16 stage control unit
17 Secondary or backscattered Electron detector
19 Control Unit
21 Position sensor
23 Scan Controller
40 charged particle beam (CPB) imaging system
42 Optical Axis of imaging system
43 Intersection point
44 Imaging charged particle beam
48 Fib Optical Axis
50 FIB column
51 focused ion beam
52 cross-section surface
53 cross-section surface
55 wafer top surface
57 scan path of imaging beam
61 image area of surface bevor milling
63 image area of surface after milling
67 line or step between different areas
155 wafer stage
160 inspection volume
163 image data stack
165 subset of cross-section images
167 stack of image slices
171 volume of interest
173 region of interest
175 averaged image of region of interest
181 sparse regions of image acquisition
307 measured cross section image of HAR structure
309 HAR structures
311 cross section image slice
313 cross sections through word lines
315 edge with surface
331 averaged image slices

What is claimed is:

1. A method of inspecting a 3D semiconductor object in an inspection volume of a wafer sample, the method comprising:
acquiring a first number of N cross-section images by fast milling and fast image scanning of a plurality of cross-section surfaces through the inspection volume; and
forming a second number of M averaged image slices from the first number of N cross-section images by computing moving average values in a predetermined direction of the semiconductor object,
wherein the moving average values for each average image slice are computed from a subset of the first number of N cross-section images.

2. The method of claim 1, wherein M is less than N.

3. The method of claim 1, wherein a ration of M to N is less than or equal to 0.95.

4. The method of claim 1, comprising fast milling of a new cross-section surface and fast image scanning to acquire a cross-section image at different times.

5. The method of claim 1, comprising performing the fast milling of a new cross-section surface and the fast image scanning to acquire a cross-section image at the same time using a scanning direction of a charged particle imaging beam which is perpendicular to a direction of a focused ion beam, wherein a cross-section image comprises a first area corresponding to a first cross-section surface before an actual fast milling operation, and a second area corresponding to a second, deeper cross-section surface according to the actual fast milling operation.

6. The method of claim 1, wherein the semiconductor object comprises an HAR channel with the predetermined direction perpendicular to a top surface of the wafer sample.

7. The method of claim 1, comprising performing the fast milling at an angle of at most 45° relative to a top surface of the sample.

8. The method of claim 1, comprising computing of moving average values over the second number of cross section images by convolution of the cross-section images with a one-dimensional convolution kernel parallel to the predetermined direction.

9. The method according to claim 8, wherein the one-dimensional convolution kernel extends over at least 3 consecutive cross section images, and the one-dimensional convolution kernel comprises a form selected from the group consisting of a weighted sum, a rect function, and a gaussian distribution function.

10. The method of claim 1, comprising, during the computing of moving average values, compensating a lateral drift of a cross-section image of the plurality of cross section images, wherein the lateral drift direction is perpendicular to the predetermined direction.

11. The method of claim 1, further comprising adjusting a distance between two adjacent cross-section surfaces according to prior information of the semiconductor object within a volume of interest.

12. The method of claim 1, further comprising adjusting a milling angle of a subsequently milled cross-section surface according to prior information of the semiconductor object within a volume of interest.

13. The method of claim 1, further comprising changing a detection mode between subsequent fast image scans, wherein a change of a detection mode comprises at least member selected from the group consisting of a change of a dynamic range, a change of an energy range of interaction products, and a change of a type of interaction products.

14. One or more machine-readable hardware storage devices comprising instructions that are executable by one or more processing devices to perform operations comprising the method of claim 1.

15. A system, comprising:
one or more processing devices; and
one or more machine-readable hardware storage devices comprising instructions that are executable by one or more processing devices to perform operations comprising the method of claim 1.

16. The system of claim 14, further comprising:
a wafer sample stage for holding and positioning a wafer sample; and
a dual column microscope comprising a first beam column and a second beam column,
wherein the first and second beam columns define a common intersection point of an optical axis of the FIB column and an optical axis of the charged particle beam imaging column.

17. The system of claim 15, wherein the first column comprises a focused ion beam column, and the second column comprises a charged particle beam imaging column.

18. A method of inspecting a 3D semiconductor object in an inspection volume of a wafer sample, the method comprising:
defining a first volume of interest within an inspection volume of a semiconductor wafer;
milling a plurality of cross section surfaces through the inspection volume; and
acquiring a number of cross section image segments by performing image scanning operations of cross-section surface segments withing the first volume of interest,
wherein each cross section image segment is determined according to regions of interest formed by the intersection of a cross-section surface with the volume of interest.

19. A method of inspecting a 3D semiconductor object in an inspection volume of a wafer sample, the comprising:
milling a plurality of cross section surfaces through the inspection volume;
selecting a plurality of sparse regions for each cross-section surface;
acquiring a plurality of sparse cross-section image segments by performing image scanning operations of the plurality of sparse regions of each cross-section surface; and
generating a 3D volume image of the inspection volume from the plurality of sparse cross section image segments.

20. A method of inspecting an inspection volume a 3D semiconductor object of a wafer sample, the comprising:
milling a plurality of cross-section surfaces through the inspection volume;
scanning each cross-section surface with an imaging charged particle beam, thereby generating interaction products comprising at least two members selected from the group consisting of secondary electrons, backscattered charged particles, photons, and x-rays in different energy ranges; and
forming a plurality of cross-section images from detection signals of at least two different interaction products.
